(19) United States
(12) Patent Application Publication
(10) Pub. No.: US 2024/0215375 A1
(43) Pub. Date: Jun. 27, 2024

(54) Display Device and Display Panel

(71) Applicant: LG Display Co., Ltd., Seoul (KR)

(72) Inventors: JungSik Jo, Paju-si (KR); ChulHo Kim, Paju-si (KR)

(21) Appl. No.: 18/501,867

(22) Filed: Nov. 3, 2023

(30) Foreign Application Priority Data
Dec. 27, 2022 (KR) 10-2022-0186204

(51) Int. Cl. H10K 59/65; G09G 3/3233; G09G 3/3266; H10K 59/122; H10K 59/80

(52) U.S. Cl. CPC H10K 59/65; G09G 3/3233; G09G 3/3266; H10K 59/122; H10K 59/80517; H10K 59/80518; H10K 59/80524; H10K 59/878; H10K 2102/351

(57) ABSTRACT

The present disclosure relates to a display panel and a display device, and more specifically, to a display panel and a display device that include: a first optical area allowing light to be transmitted; and a normal area included in a display area and located outside of the first optical area, the first optical area comprising: a first anode electrode of a first light emitting element; a first insulating layer including a concave portion exposing at least a portion of an upper surface of the first anode electrode; a light path changing element disposed on a portion of an upper surface of the insulating layer and a side surface of the concave portion; and a bank exposing a portion of the light path changing element disposed on the upper surface of the insulating layer and exposing a portion of the upper surface of the first anode electrode, and are capable of improving light extraction efficiency.

### CROSS-REFERENCE TO RELATED APPLICATION

This application claims the priority and benefit of Republic of Korea Patent Application No. 10-2022-0186204, filed on Dec. 27, 2022 in the Korean Intellectual Property Office, which is incorporated herein by reference in its entirety for all purposes.

### BACKGROUND

### Technical Field

The present disclosure relates to electronic devices, and more specifically, for example, without limitation, to a display device and a display panel.

### Description of the Related Art

As display technology advances, display devices can provide increased functions, such as an image capture function, a sensing function, and the like, in addition to an image display function. To provide these functions, a display device may need to include one or more optical electronic devices, such as a camera, a sensor for detecting light or an image, and the like.

The description provided in the background section should not be assumed to be prior art merely because it is mentioned in or associated with the background section. The background section may include information that describes one or more aspects of the subject technology.

### SUMMARY

In order to receive light passing through a front surface of a display device, it may be desirable for such an optical electronic device to be located in an area of the display device where incident light coming from the front surface can be increasingly received and detected. To achieve the foregoing, in a typical display device, an optical electronic device has been designed to be located in a front portion of the display device to allow a camera, a sensor, and/or the like as the optical electronic device to be increasingly exposed to incident light. In order to install an optical electronic device in a display device in this manner, a bezel area of the display device may be increased, or a notch or a hole may be needed to be formed in a display area of an associated display panel.

Therefore, as a display device needs an optical electronic device to receive or detect incident light, and perform an intended function, a size of the bezel in the front portion of the display device may be increased, or a substantial disadvantage may be encountered in designing the front portion of the display device.

In addition, in examples where a display device includes an optical electronic device, the quality of images may be unexpectedly decreased according to structures in which the optical electronic device is configured in the display device.

To address these issues, one or more embodiments of the present disclosure may provide a display panel and a display device that include a light transmission structure for enabling at least one optical electronic device to normally receive light (e.g., visible light, infrared light, ultraviolet light, or the like) while not being exposed in a front surface of the display device.

One or more embodiments of the present disclosure may provide a display panel and a display device that, in arranging light emitting elements and pixel circuits for driving the light emitting elements in an optical area, include an arrangement structure of capable of improving the transmittance of the optical area.

One or more embodiments of the present disclosure may provide a display panel and a display device that are capable of producing uniform luminance by preventing voltage drop in a cathode electrode disposed in an optical area.

One or more embodiments of the present disclosure may provide a display panel and a display device that are capable of being driven with low power by improving emission efficiency in an optical area.

According to aspects of the present disclosure, a display panel and a display device can be provided that include: a first optical area included in a display area in which an image can be displayed and allowing light to be transmitted; and a normal area included in the display area and located outside of the first optical area, the first optical area comprising: a first anode electrode of a first light emitting element; a first insulating layer including a concave portion exposing at least a portion of an upper surface of the first anode electrode; a light path changing element disposed on a portion of an upper surface of the insulating layer and at least one side surface of the concave portion; and a bank exposing a portion of the light path changing element disposed on the upper surface of the insulating layer and exposing a portion of the upper surface of the first anode electrode.

According to aspects of the present disclosure, a display panel and a display device can be provided that include: a first optical area included in a display area in which an image can be displayed and allowing light to be transmitted; a normal area included in the display area and located outside of the first optical area; and a first optical bezel area included in the display area and located between the first optical area and the normal area, the first optical area comprising: a first anode electrode of a first light emitting element; a first insulating layer including a concave portion exposing at least a portion of an upper surface of the first anode electrode; a light path changing element disposed on a portion of an upper surface of the insulating layer and at least one side surface of the concave portion; and a bank exposing a portion of the light path changing element disposed on the upper surface of the insulating layer and exposing a portion of the upper surface of the first anode electrode.

According to one or more embodiments of the present disclosure, a display panel and a display device may be provided that include a light transmission structure for enabling one or more optical electronic devices to normally receive light (e.g., visible light, infrared light, ultraviolet light, or the like) while not being exposed in a front surface of the display device.

According to one or more embodiments of the present disclosure, a display panel and a display device may be provided that are capable of more improving transmittance of an optical area by disposing light emitting elements in the optical area allowing light to be transmitted, but disposing pixel circuits for driving the light emitting elements of the optical area in an area outside of the optical area (e.g., an optical bezel area, a normal area).

According to one or more embodiments of the present disclosure, a display panel and a display device may be provided that include a structure of interconnecting, using anode extension lines including a transparent material, light emitting elements disposed in an optical area allowing light to be transmitted and pixel circuits (e.g., transistors included in the pixel circuits) disposed in an area outside of the optical area (e.g., an optical bezel area, a normal area), and thereby, are capable of increasingly improving transmittance of an optical area.

According to one or more embodiments of the present disclosure, a display panel and a display device may be provided that are capable of producing high luminance even when driven with low power by improving light extraction efficiency through a light path changing element disposed in an optical area.

According to one or more embodiments of the present disclosure, a display panel and a display device may be provided that allow a light path changing element and a cathode electrode disposed in an optical area to contact, and thereby, are capable of producing uniform luminance by preventing voltage drop in the cathode electrode.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIGS. 1A, 1B, and 1C illustrate an example display device according to aspects of the present disclosure;

FIG. 2 illustrates an example system configuration of the display device according to aspects of the present disclosure;

FIG. 3 illustrates an example display panel according to aspects of the present disclosure;

FIG. 4 schematically illustrates an example first type of first optical area and an example normal area around the first type of first optical area in the display panel according to aspects of the present disclosure;

FIG. 5 illustrates example light emitting elements disposed in a normal area, a first optical bezel area, and a first optical area, and examples pixel circuits for driving the light emitting elements in the display panel according to aspects of the present disclosure;

FIG. 6 illustrates example light emitting elements disposed in the normal area, the first optical bezel area, and the first optical area, and example pixel circuits for driving the light emitting elements in the display panel according to aspects of the present disclosure;

FIG. 7 is an example plan view of the normal area, the first optical bezel area, and the first optical area included in the display panel according to aspects of the present disclosure;

FIG. 8 is an example cross-sectional view taken along line X-Y of FIG. 7;

FIG. 9 is an example cross-sectional view taken along line A-B of FIG. 7;

FIGS. 10 and 11 are example cross-sectional views of the display panel according to aspects of the present disclosure, and illustrate example structures capable of preventing a voltage drop through a contact between an emission layer and a first cathode electrode of a light emitting element;

FIG. 12 illustrates an example first light emitting area and an example first auxiliary light emitting area included in the first optical area in the display panel according to aspects of the present disclosure;

FIG. 13 is an example cross-sectional view of the display panel according to aspects of the present disclosure in an example where a one-to-two (1:2) circuit connection scheme as shown in FIG. 6 is applied; and

FIG. 14 illustrates an example normal area, and an example second optical area included in the display panel according to aspects of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference. The terms, such as “below,” “lower,” “above,” “upper” and the like, may be used herein to describe a relationship between item(s) as illustrated in the drawings. It will be understood that the terms are spatially relative and based on the orientation depicted in the drawings.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various embodiments of the present disclosure will be described in detail with reference to the accompanying drawings. In addition, for convenience of description, a scale in which each of elements is illustrated in the accompanying drawings may differ from an actual scale. Thus, the illustrated elements are not limited to the specific scale in which they are illustrated in the drawings.

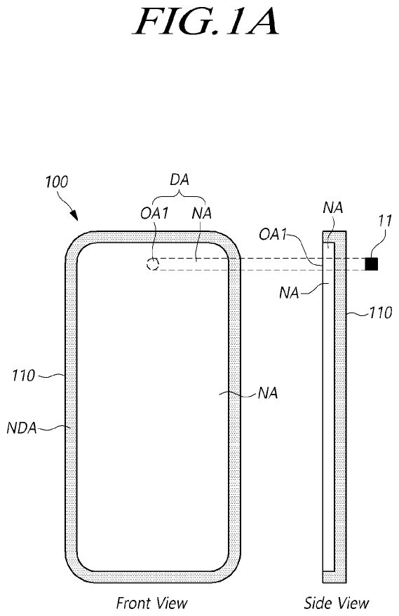

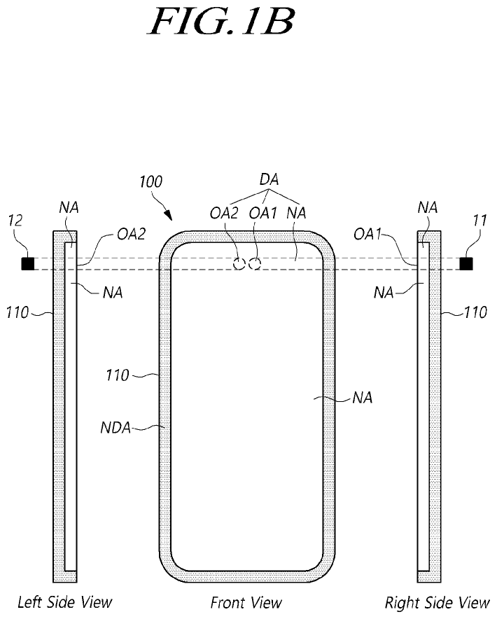

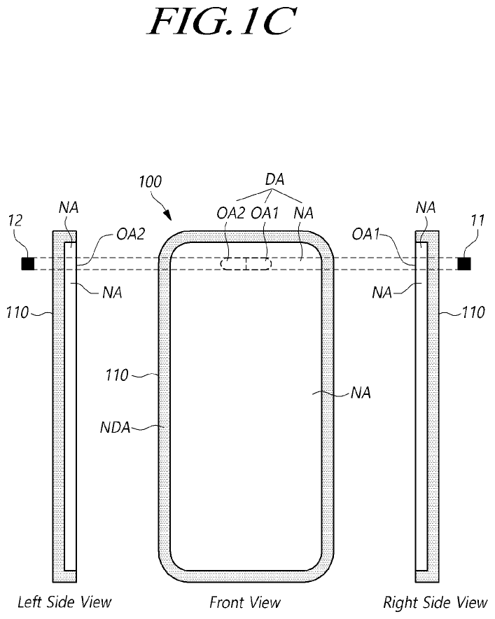

FIGS. 1A, 1B, and 1C illustrate an example display device according to aspects of the present disclosure.

Referring to FIGS. 1A, 1B, and 1C, in one or more exemplary embodiments, a display device 100 according to aspects of the present disclosure may include a display panel 110 for displaying one or more images, and one or more optical electronic devices (11 and/or 12). Herein, an optical electronic device may be referred to as a light detector, a light receiver, or a light sensing device, without being limited thereto. An optical electronic device may include one or more of a camera, a camera lens, a sensor, a sensor for detecting images, or the like, without being limited thereto.

The display panel 110 may include a display area DA in which one or more images can be displayed and a non-display area NDA in which an image is not displayed.

A plurality of subpixels may be arranged in the display area DA, and several types of signal lines for driving the plurality of subpixels may be arranged therein.

The non-display area NDA may refer to an area outside of the display area DA. As an example, the non-display area NDA may be adjacent to the display area DA. As an example, the non-display area NDA may partially or fully surround the display area DA. As an example, several types of signal lines may be arranged in the non-display area NDA, and several types of driving circuits may be connected thereto. As an example, at least a portion of the non-display area NDA may be bent to be invisible from the front surface of the display device 100 or may be covered by a case or housing (not shown) of the display device 100, without being limited thereto. The non-display area NDA may be also referred to as a bezel or a bezel area.

Referring to FIGS. 1A, 1B, and 1C, in one or more embodiments, in the display device 100 according to aspects of the present disclosure, one or more optical electronic devices (11 and/or 12) may be prepared independently of, and installed in, the display panel 110, and be located under, or in a lower portion of, the display panel 110 (an opposite side of a viewing surface thereof). Embodiments are not limited thereto. As an example, one or more optical electronic devices (11 and/or 12) may be integrally prepared with the display panel 110.

Light can enter the front surface (the viewing surface) of the display panel 110, pass through the display panel 110, reach one or more optical electronic devices (11 and/or 12) located under, or in the lower portion of, the display panel 110 (the opposite side of the viewing surface). Light passing through the display panel 110 may include, for example, visible light, infrared light, or ultraviolet light.

The one or more optical electronic devices (11 and/or 12) may be devices capable of receiving or detecting light passing through the display panel 110 and perform a predefined function based on the received light, without being limited thereto. For example, the one or more optical electronic devices (11 and/or 12) may include one or more of the following: an image capture device such as a camera (an image sensor), and/or the like; or a sensor such as a proximity sensor, an illuminance sensor, and/or the like. Such a sensor may be, for example, an infrared sensor capable of detecting infrared light.

Referring to FIGS. 1A, 1B, and 1C, in one or more exemplary embodiments, the display area DA of the display panel 110 according to aspects of the present disclosure may include one or more optical areas (OA1 and/or OA2) and a normal area NA. Herein, the term “normal area” NA is an area that while being present in the display area DA, does not overlap with one or more optical electronic devices (11 and/or 12) and may also be referred to as a non-optical area. The one or more optical areas (OA1 and/or OA2) may be one or more areas respectively overlapping the one or more optical electronic devices (11 and/or 12) in a cross-sectional view of the display panel 110.

According to an example of FIG. 1A, the display area DA may include a first optical area OA1 and a normal area NA. In this example, at least a portion of the first optical area OA1 may overlap a first optical electronic device 11.

According to an example of FIG. 1B, the display area DA may include a first optical area OA1, a second optical area OA2, and a normal area NA. In this example, a portion of the normal area NA may be present between the first optical area OA1 and the second optical area OA2. At least a portion of the first optical area OA1 may overlap the first optical electronic device 11, and at least a portion of the second optical area OA2 may overlap a second optical electronic device 12.

According to an example of FIG. 1C, the display area DA may include a first optical area OA1, a second optical area OA2, and a normal area NA. In this example, the normal area NA may not be present between the first optical area OA1 and the second optical area OA2. For example, the first optical area OA1 and the second optical area OA2 may contact each other (e.g., directly contact each other). In this example, at least a portion of the first optical area OA1 may overlap the first optical electronic device 11, and at least a portion of the second optical area OA2 may overlap the second optical electronic device 12.

In the display panel 110 or the display device 100 according to aspects of the present disclosure, it may be desirable that both an image display structure and a light transmission structure are implemented in at least one of the one or more optical areas (OAl and/or OA2). For example, since the one or more optical areas (OAl and/or OA2) are portions of the display area DA, it may be therefore desirable that light emitting areas of subpixels for displaying one or more images are disposed in at least one of the one or more optical areas (OA1 and/or OA2). Further, to enable light to be transmitted to the one or more optical electronic devices (11 and/or 12), it may be desirable that a light transmission structure is implemented in the one or more optical areas (OA1 and/or OA2).

It should be noted that even though the one or more optical electronic devices (11 and/or 12) are devices that need to receive light, at least one of the one or more optical electronic devices (11 and/or 12) may be located on the back of the display panel 110 (e.g., on an opposite side of the viewing surface thereof), and thereby, can receive light that has passed through the display panel 110. For example, at least one of the one or more optical electronic devices (11 and/or 12) may not be exposed in the front surface (viewing surface) of the display panel 110 or the display device 100. Accordingly, when a user faces the front surface of the display device 110, at least one of the one or more optical electronic devices (11 and/or 12) are located so that they cannot be visible to the user.

The first optical electronic device 11 may be, for example, a camera, and the second optical electronic device 12 may be, for example, a sensorThe sensor may be a proximity sensor, an illuminance sensor, an infrared sensor, and/or the like. In one or more embodiments, the camera may be a camera lens, an image sensor, or a unit including at least one of the camera lens and the image sensor, and the sensor may be an infrared sensor capable of detecting infrared light. In another embodiment, the first optical electronic device 11 may be a sensor, and the second optical electronic device 12 may be a camera. Embodiments are not limited thereto. As an example, both of the first optical electronic device 11 and the second optical electronic device 12 may be a camera or a sensor.

Hereinafter, for convenience of descriptions related to the optical electronic devices (11 and 12), the first optical electronic device 11 is considered to be a camera, and the second optical electronic device 12 is considered to be an infrared sensor. It should be, however, understood that the scope of the present disclosure includes examples where the first optical electronic device 11 is a sensor or a camara, and the second optical electronic device 12 is a camera or a sensor. The camera may be, for example, a camera lens, an image sensor, or a unit including at least one of the camera lens and the image sensor.

In an example where the first optical electronic device 11 is a camera, this camera may be located on the back of (e.g., under, or in a lower portion of) the display panel 110, and be a front camera capable of capturing objects or images in a front direction of the display panel 110. Accordingly, the user can capture an image or object through the camera that is invisible on the viewing surface while looking at the viewing surface of the display panel 110.

Although the normal area NA and the one or more optical areas (OA1 and/or OA2) included in the display area DA in each of FIGS. 1A, 1B, and 1C are areas where images are allowed to be displayed, the normal area NA is an area where a light transmission structure need not be implemented, but the one or more optical areas (OA1 and/or OA2) are areas where a light transmission structure need be implemented. Thus, in one or more exemplary embodiments, the normal area NA is an area where a light transmission structure is not implemented or included, and the one or more optical areas (OA1 and/or OA2) are areas in which a light transmission structure is implemented or included.

Accordingly, the one or more optical areas (OA1 and/or OA2) can have a transmittance greater than or equal to a predetermined level, i.e., a relatively high transmittance, and the normal area NA can have a transmittance less than the predetermined level or not have light transmittance.

For example, the one or more optical areas (OA1 and/or OA2) may have a resolution, a subpixel arrangement structure, a number of subpixels per unit area, an electrode structure, a line structure, an electrode arrangement structure, a line arrangement structure, and/or the like different from that/those of the normal area NA.

In one embodiment, the number of subpixels per unit area in the one or more optical areas (OA1 and/or OA2) may be less than the number of subpixels per unit area in the normal area NA. For example, the resolution of the one or more optical areas (OA1 and/or OA2) may be lower than that of the normal area NA. In this example, the number of subpixels per unit area may have the same meaning as a resolution, a pixel density, or a degree of integration of pixels. For example, the unit of the number of subpixels per unit area may be pixels per inch (PPI), which represents the number of pixels within 1 inch.

In the examples of FIGS. 1A, 1B, and 1C, the number of subpixels per unit area in the first optical areas OA1 may be less than the number of subpixels per unit area in the normal area NA. In the examples of FIGS. 1B and 1C, the number of subpixels per unit area in the second optical areas OA2 may be greater than or equal to the number of subpixels per unit area in the first optical areas OA1, and be less than the number of subpixels per unit area in the normal area NA. Embodiments are not limited thereto. As an example, the number of subpixels per unit area in the second optical areas OA2 may be smaller than the number of subpixels per unit area in the first optical areas OA1.

In one or more embodiments, as a method for increasing respective transmittance of at least one of the first optical area OA1 and the second optical area OA2, a pixel density differentiation design scheme as described above may be applied in which a difference in densities of pixels (or subpixels) or in degrees of integration of pixels (or subpixels) between the first optical area OA1, the second optical area OA2, and the normal area NA can be produced. According to the pixel density differentiation design scheme, in an embodiment, the display panel 110 may be configured or designed such that the number of subpixels per unit area of at least one of the first optical area OA1 and the second optical area OA2 is smaller than the number of subpixels per unit area of the normal area NA.

In one or more embodiments, as another method for increasing respective transmittance of at least one of the first optical area OA1 and the second optical area OA2, a pixel size differentiation design scheme may be applied in which a difference in sizes of pixels (or subpixels) between the first optical area OA1, the second optical area OA2, and the normal area NA can be produced. According to the pixel size differentiation design scheme, the display panel 110 may be configured or designed such that while the number of subpixels per unit area of at least one of the first optical area OA1 and the second optical area OA2 is equal to or similar to the number of subpixels per unit area of the normal area NA, a size of each subpixel (i.e., a size of a corresponding light emitting area) disposed in at least one of the first optical area OA1 and the second optical area OA2 is smaller than a size of each subpixel (i.e., a size of a corresponding light emitting area) disposed in the normal area NA.

In one or more aspects, for convenience of description, discussions that follow are provided based on the pixel density differentiation design scheme of the two schemes (i.e., the pixel density differentiation design scheme and the pixel size differentiation design scheme) for increasing respective transmittance of at least one of the first optical area OA1 and the second optical area OA2, unless explicitly stated otherwise. It should be therefore understood that in descriptions that follow, a small number of subpixels per unit area may be considered as corresponding to a small size of subpixel, and a large number of subpixels per unit area may be considered as corresponding to a large size of subpixel.

In the examples of FIGS. 1A, 1B, and 1C, the first optical area OA1 may have various shapes, such as a circle, an ellipse, a quadrangle, a hexagon, an octagon or the like. In the examples of FIGS. 1B and 1C, the second optical area OA2 may have various shapes, such as a circle, an ellipse, a quadrangle, a hexagon, an octagon or the like. The first optical area OA1 and the second optical area OA2 may have the same or substantially or nearly the same shape, or different shapes.

Referring to FIG. 1C, in the example where the first optical area OA1 and the second optical area OA2 contact each other (e.g., directly contact each other), the entire optical area including the first optical area OA1 and the second optical area OA2 may also have various shapes, such as a circle, an ellipse, a quadrangle, a hexagon, an octagon or the like. Hereinafter, for convenience of descriptions related to shapes of the optical areas (OA1 and OA2), each of the first optical area OA1 and the second optical area OA2 is considered to have a circular shape. It should be, however, understood that the scope of the present disclosure includes examples where at least one of the first optical area OA1 and the second optical area OA2 have a shape other than a circular shape.

According to one or more aspects of the present disclosure, when the display device 100 has a structure in which the first optical electronic device 11 such as a camera, and the like is located under, or in a lower portion of, the display panel 100 without being exposed to the outside, such a display device may be referred to as a display to which an under-display camera (UDC) technology is applied.

The display device 100 to which such an under-display camera (UDC) technology is applied can provide an advantage of reducing or preventing a reduction of an area or size of the display area DA because a notch or a camera hole for exposing a camera need not be formed in the display panel 110. Indeed, since a notch or a camera hole for camera exposure need not be formed in the display panel 110, the display device 100 can provide further advantages of reducing the size of a bezel area, and improving the degree of freedom in design because such limitations to the design are removed.

Although the one or more optical electronic devices (11 and/or 12) are located on the back of (e.g., under, or in a lower portion of) the display panel 110 of the display device 100 (e.g., hidden or not exposed to the outside), the one or more optical electronic devices (11 and/or 12) are required to perform their normal predefined functionalities by receiving or detecting light.

Further, although one or more optical electronic devices (11 and/or 12) are located on the back of (e.g., under, or in a lower portion of) the display panel 110 to be hidden and located to be overlap the display area DA, it is desirable that the display device 100 is configured to normally display one or more images in the one or more optical areas (OA1 and/or OA2) overlapping the one or more optical electronic devices (11 and/or 12) in the display area DA. Thus, even though one or more optical electronic devices (11 and/or 12) are located on the back of the display panel, the display device 100 according to aspects of the present disclosure can be configured to display images in a normal manner (e.g., without or with little reduction in image quality) in the one or more optical areas (OA1 and/or OA2) overlapping the one or more optical electronic devices (11 and/or 12) in the display area DA.

Since the foregoing first optical area OA1 is configured or designed as an optically transmissive area, the quality of image display in the first optical area OA1 may be different from the quality of image display in the normal area NA.

Further, when designing the first optical area OA1 for the purpose of improving the quality of image display, there may be caused a situation that the transmittance of the first optical area OA1 is reduced.

To address these issues, in one or more aspects, the first optical area OA1 included in the display device 100 or the display panel may be configured with, or include, a structure capable of reducing or preventing a difference (e.g., non-uniformity) in image quality between the first optical area OA1 and the normal area NA from being caused, and improving the transmittance of the first optical area OA1.

Further, one or more exemplary embodiments may provide not only the structure of the first optical area OA1, but a structure of the second optical area OA2 that is capable of improving the image quality of the second optical area OA2, and improving the transmittance of the second optical area OA2.

It should be also noted that the first optical area OA1 and the second optical area OA2 included in the display device 100 or the display panel 110 according to aspects of the present disclosure may be differently implemented or have different utilization examples while having a similarity in terms of light transmittable areas. Taking account of such a distinction, the structure of the first optical area OA1 and the structure of the second optical area OA2 in the display device 100 according to aspects of the present disclosure may be configured or designed differently from each other. Embodiments are not limited thereto. As an example, the first optical area OA1 and the second optical area OA2 included in the display device 100 or the display panel 110 according to aspects of the present disclosure may be identically or similarly implemented or have the same or similar utilization examples.

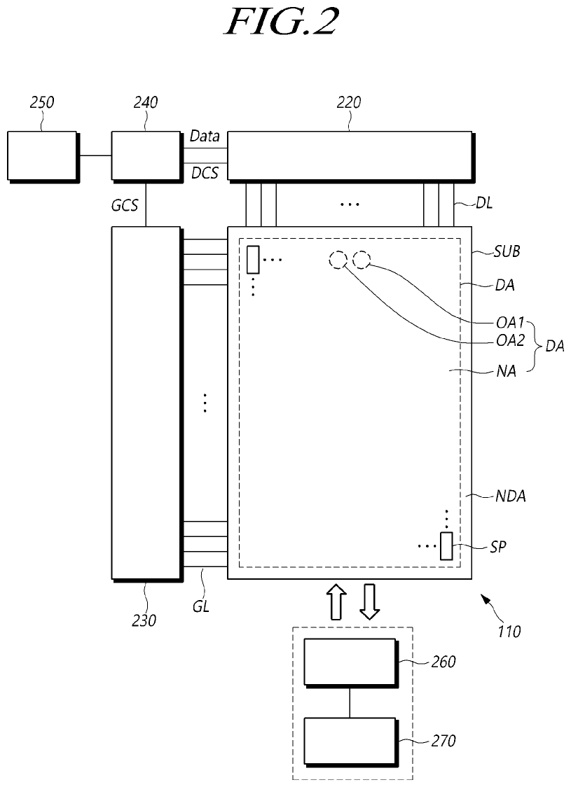

FIG. 2 illustrates an example system configuration of the display device 100 according to aspects of the present disclosure.

FIG. 2 illustrates an example configuration of the display device 100 according to one or more exemplary embodiments of the present disclosure. Referring to FIG. 2, the display device 100 may include the display panel 110 and a display driving circuit as components for displaying one or more images.

The display driving circuit may be a circuit for driving the display panel 110, and include a data driving circuit 220, a gate driving circuit 230, a display controller 240, and other circuit components.

The display panel 110 may include a display area DA in which one or more images can be displayed and a non-display area NDA in which an image is not displayed. The non-display area NDA may be an area outside of the display area DA, and may also be referred to as an edge area or a bezel area. All or at least a portion of the non-display area NDA may be an area visible from the front surface of the display device 100, or an area that is bent and invisible from the front surface of the display device 100.

The display panel 110 may include a substrate SUB and a plurality of subpixels SP disposed on the substrate SUB. The display panel 110 may further include various types of signal lines to drive the plurality of subpixels SP.

In one or more embodiments, the display device 100 according to aspects of the present disclosure may be a liquid crystal display device, or the like, or a self-emission display device in which light is emitted from the display panel 110 itself. In the example where the display device 100 according to aspects of the present disclosure is implemented as a self-emission display device, each of the plurality of subpixels SP may include a light emitting element. For example, the display device 100 according to aspects of the present disclosure may be an organic light emitting display device implemented with one or more organic light emitting diodes (OLED). In another example, the display device 100 according to aspects of the present disclosure may be an inorganic light emitting display device implemented with one or more inorganic material-based light emitting diodes. In further another example, the display device 100 according to aspects of the present disclosure may be a quantum dot display device implemented with quantum dots, which are self-emission semiconductor crystals. Embodiments are not limited thereto

The structure of each of the plurality of subpixels SP may be differently configured or designed according to types of the display devices 100. For example, in an example where the display device 100 is a self-emission display device including self-emission subpixels SP, each subpixel SP may include a self-emission light emitting element, one or more transistors, and one or more capacitors.

In one or more embodiments, various types of signal lines arranged in the display device 100 may include, for example, a plurality of data lines DL for carrying data signals (which may be referred to as data voltages or image signals), a plurality of gate lines GL for carrying gate signals (which may be referred to as scan signals or emission control signals), and the like.

The plurality of data lines DL and the plurality of gate lines GL may intersect one another. Each of the plurality of data lines DL may extend in a first direction. Each of the plurality of gate lines GL may extend in a second direction different from the first direction. For example, the first direction may be a column or vertical direction, and the second direction may be a row or horizontal direction. In another example, the first direction may be the row or horizontal direction, and the second direction may be the column or vertical direction.

The data driving circuit 220 may be a circuit for driving the plurality of data lines DL, and can supply data signals to the plurality of data lines DL. The gate driving circuit 230 may be a circuit for driving the plurality of gate lines GL, and can supply gate signals to the plurality of gate lines GL.

The display controller 240 may be a device for controlling the data driving circuit 220 and the gate driving circuit 230, and can control driving times for the plurality of data lines DL and driving times for the plurality of gate lines GL.

The display controller 240 can supply a data driving control signal DCS to the data driving circuit 220 to control the data driving circuit 220, and supply a gate driving control signal GCS to the gate driving circuit 230 to control the gate driving circuit 230.

The display controller 240 can receive input image data from a host system 250 and supply image data Data based on the input image data to the data driving circuit 220.

The data driving circuit 220 can receive digital image data Data from the display controller 240, convert the received image data Data into analog data signals, and output the resulting analog data signals to the plurality of data lines DL.

The gate driving circuit 230 can receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

In one or more embodiments, the data driving circuit 220 may be connected to the display panel 110 using a tape-automated-bonding (TAB) technique, or connected to a conductive pad such as a bonding pad of the display panel 110 using a chip-on-glass (COG) technique or a chip-on-panel (COP) technique, or connected to the display panel 110 using a chip-on-film (COF) technique, without being limited thereto. As an example, the data driving circuit 220 may be disposed in the non-display area NDA of the display panel 110 using a gate-in-panel (GIP) technique.

In one or more embodiments, the gate driving circuit 230 may be connected to the display panel 110 using the tape-automated-bonding (TAB) technique, or connected to a conductive pad such as a bonding pad of the display panel 110 using the chip-on-glass (COG) technique or the chip-on-panel (COP) technique, or connected to the display panel 110 using the chip-on-film (COF) technique. In one or more exemplary embodiments, the gate driving circuit 230 may be disposed in the non-display area NDA of the display panel 110 using a gate-in-panel (GIP) technique. The gate driving circuit 230 may be disposed on the substrate, or connected to the substrate. In an example where the gate driving circuit 230 is implemented with the GIP technique, the gate driving circuit 230 may be disposed in the non-display area NDA of the substrate SUB. The gate driving circuit 230 may be connected to the substrate SUB in an example where the gate driving circuit 230 is implemented with the chip-on-glass (COG) technique, the chip-on-film (COF) technique, or the like.

In one or more exemplary embodiments, at least one of the data driving circuit 220 and the gate driving circuit 230 may be disposed in the display area DA of the display panel 110. For example, at least one of the data driving circuit 220 and the gate driving circuit 230 may be disposed such that it does not overlap subpixels SP, or disposed such that it overlaps one or more, or all, of the subpixels SP, or at least respective one or more portions of one or more subpixels.

The data driving circuit 220 may be located in, and/or electrically connected to, but not limited to, only one side or portion (e.g., an upper edge or a lower edge) of the display panel 110. In one or more exemplary embodiments, the data driving circuit 220 may be located in, and/or electrically connected to, but not limited to, two sides or portions (e.g., an upper edge and a lower edge) of the display panel 110 or at least two of four sides or portions (e.g., the upper edge, the lower edge, a left edge, and a right edge) of the display panel 110 according to driving schemes, panel design schemes, or the like.

The gate driving circuit 230 may be located in, and/or electrically connected to, but not limited to, only one side or portion (e.g., a left edge or a right edge) of the display panel 110. In one or more exemplary embodiments, the gate driving circuit 230 may be located in, and/or electrically connected to, but not limited to, two sides or portions (e.g., a left edge and a right edge) of the panel 110 or at least two of four sides or portions (e.g., an upper edge, a lower edge, the left edge, and the right edge) of the panel 110 according to driving schemes, panel design schemes, or the like.

The display controller 240 may be implemented in a separate component from the data driving circuit 220, or incorporated in the data driving circuit 220 and thus implemented in an integrated circuit.

The display controller 240 may be a timing controller used in the typical display technology or a controller or a control device capable of performing other control functions in addition to the function of the typical timing controller. In one or more exemplary embodiments, the display controller 140 may be a controller or a control device different from the timing controller, or a circuitry or a component included in the controller or the control device. The display controller 240 may be implemented with various circuits or electronic components such as an integrated circuit (IC), a field programmable gate array (FPGA), an application specific integrated circuit (ASIC), a processor, and/or the like.

The display controller 240 may be mounted on a printed circuit board, a flexible printed circuit, and/or the like and be electrically connected to the gate driving circuit 220 and the data driving circuit 230 through the printed circuit board, flexible printed circuit, and/or the like.

The display controller 240 may transmit signals to, and receive signals from, the data driving circuit 220 via one or more predefined interfaces. For example, such interfaces may include a low voltage differential signaling (LVDS) interface, an embedded clock point-point interface (EPI), a serial peripheral interface (SPI), and the like.

In one or more embodiments, in order to further provide a touch sensing function, in addition to an image display function, the display device 100 according to aspects of the present disclosure may optionally include at least one touch sensor, and a touch sensing circuit capable of detecting the occurrence of a touch event by a touch object such as a finger, a pen, or the like, or of detecting a corresponding touch position (or touch coordinates), by sensing the touch sensor.

The touch sensing circuit may include a touch driving circuit 260 capable of generating and providing touch sensing data by driving and sensing the touch sensor, a touch controller 270 capable of detecting the occurrence of a touch event or detecting a touch position (or touch coordinates) using the touch sensing data, and one or more other components.

The touch sensor may include a plurality of touch electrodes. The touch sensor may further include a plurality of touch lines for electrically connecting the plurality of touch electrodes to the touch driving circuit 260.

The touch sensor may be implemented in the form of a touch panel outside of the display panel 110 or be integrated inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes on the touch panel substrate.

In the example where the touch sensor is integrated inside of the display panel 110, the touch sensor may be formed on the substrate SUB together with signal lines and electrodes related to display driving during a process of manufacturing the display panel 110.

The touch driving circuit 260 can supply a touch driving signal to at least one of a plurality of touch electrodes, and sense at least one of the plurality of touch electrodes to generate touch sensing data.

The touch sensing circuit can perform touch sensing using a self-capacitance sensing technique or a mutual-capacitance sensing technique.

In the example where the touch sensing circuit performs touch sensing using the self-capacitance sensing technique, the touch sensing circuit can perform touch sensing based on capacitance between at least one touch electrode and a touch object (e.g., a finger, a pen, and the like). According to the self-capacitance sensing technique, each of the plurality of touch electrodes can serve as both a driving touch electrode and a sensing touch electrode. The touch driving circuit 260 can drive all, or one or more, of the plurality of touch electrodes and sense all, or one or more, of the plurality of touch electrodes.

In the example where the touch sensing circuit performs touch sensing using the mutual-capacitance sensing technique, the touch sensing circuit can perform touch sensing based on capacitance between touch electrodes. According to the mutual-capacitance sensing technique, the plurality of touch electrodes are divided into driving touch electrodes and sensing touch electrodes. The touch driving circuit 260 can drive the driving touch electrodes and sense the sensing touch electrodes.

The touch driving circuit 260 and the touch controller 270 included in the touch sensing circuit may be implemented in separate devices or in a single device. Further, the touch driving circuit 260 and the data driving circuit 220 may be implemented in separate devices or in a single device.

The display device 100 may further include a power supply circuit for supplying various types of power to the display driving circuit and/or the touch sensing circuit.

In one or more exemplary embodiments, the display device 100 according to aspects of the present disclosure may represent, but not limited to, a mobile terminal, such as a smart phone, a tablet, or the like, a monitor, a television (TV), navigation apparatuses, automotive navigation apparatuses, automotive display apparatuses, automotive apparatuses, theater apparatuses, theater display apparatuses, wall paper display apparatuses, signage apparatuses, game machines, notebook computers, cameras, camcorders, and home appliances, or the like. Embodiments of the present disclosure are not limited thereto. In one or more embodiments, the display device 100 may be display devices, or include displays, of various types, sizes, and shapes for displaying information or images.

As described above, the display area DA of the display panel 110 may include the normal area NA and the one or more optical areas (OA1 and/or OA2) as illustrated in FIGS. 1A, 1B, and 1C. The normal area NA and the one or more optical areas (OA1 and/or OA2) may be areas where images can be displayed. It should be noted here that the normal area NA may be an area in which a light transmission structure need not be implemented, and the one or more optical areas (OA1 and/or OA2) may be areas in which a light transmission structure need be implemented. Embodiments are not limited thereto. As an example, a light transmission structure may also be implemented in the normal area NA.

As discussed above with respect to the examples of FIGS. 1A, 1B, and 1C, even though the display area DA of the display panel 110 may include the one or more optical areas (OA1 and/or OA2) together with the normal area NA, for convenience of description, discussions that follow will be provided based on examples where the display area DA includes both the first and second optical areas OA1 and OA2 (i.e., the first optical area OA1 of FIGS. 1A, 1B, and 1C, and the second optical area OA2 of FIGS. 1B and 1C) and the normal area NA (i.e., the normal area NA of FIGS. 1A, 1B, and 1C).

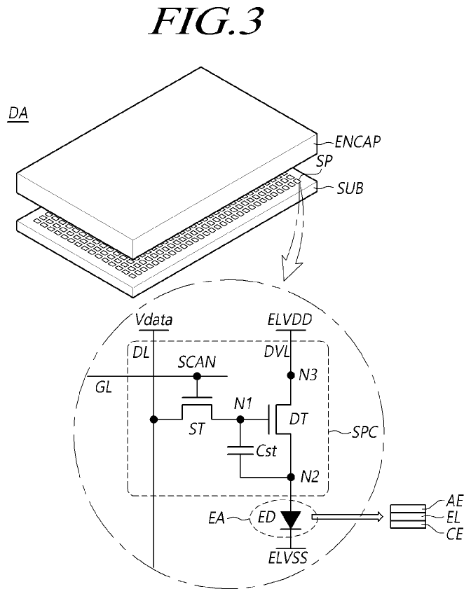

FIG. 3 illustrates an example configuration of the display panel 110 according to aspects of the present disclosure.

Referring to FIG. 3, a plurality of subpixels SP may be disposed in the display area DA of the display panel 110. The plurality of subpixels SP may be disposed in a normal area (e.g., the normal area of FIGS. 1A, 1B, and 1C), a first optical area (e.g., the first optical area OA1 of FIGS. 1A, 1B, and 1C), and a second optical area (e.g., the second optical area OA2 of FIGS. 1B and 1C) included in the display area DA of the display panel 110.

Referring to FIG. 3, each of the plurality of subpixels SP may include a light emitting element ED and a pixel circuit SPC configured to drive the light emitting element ED.

Referring to FIG. 3, the pixel circuit SPC may include a driving transistor DT for driving the light emitting element ED, a scan transistor ST for transferring a data voltage Vdata to a first node N1 of the driving transistor DT, a storage capacitor Cst for maintaining a voltage at an approximate constant level during, for example, one frame, and the like.

The driving transistor DT may include the first node N1 to which a data voltage is applied, a second node N2 electrically connected to the light emitting element ED, and a third node N3 to which a driving voltage ELVDD is applied through a driving voltage line DVL. In the driving transistor DT, the first node N1 may be a gate node, the second node N2 may be a source node or a drain node, and the third node N3 may be the drain node or the source node. For convenience of description, descriptions that follow will be provided based on examples where the first, second and third nodes (N1, N2 and N3) of the driving transistor DT are gate, source and drain nodes, respectively, unless explicitly stated otherwise. However, it should be understood that the scope of the present disclosure includes examples where the first, second and third nodes (N1, N2 and N3) of the driving transistor DT are gate, drain and source nodes, respectively.

The light emitting element ED may include an anode electrode AE, an emission layer EL, and a cathode electrode CE. The anode electrode AE may represent a pixel electrode disposed in each subpixel SP, and may be electrically connected to the second node N2 of the driving transistor DT of each subpixel SP. The cathode electrode CE may represent a common electrode being disposed in the plurality of subpixels SP in common, and a base voltage ELVSS such as a low-level voltage, a ground voltage, or the like may be applied to the cathode electrode CE. Embodiments are not limited thereto. As an example, the anode electrode AE may also be disposed in at least some of the plurality of subpixels SP in common. As an example, the cathode electrode CE may represent a common electrode being disposed in at least some of the plurality of subpixels SP in common, or may be disposed separately in each subpixel SP.

For example, the anode electrode AE may be a pixel electrode, and the cathode electrode CE may be a common electrode. In another example, the anode electrode AE may be a common electrode, and the cathode electrode CE may be a pixel electrode. For convenience of description, discussions that follow will be provided based on examples where the anode electrode AE is a pixel electrode, and the cathode electrode CE is a common electrode unless explicitly stated otherwise. However, it should be understood that the scope of the present disclosure includes examples where the anode electrode AE is a common electrode, and the cathode electrode CE is a pixel electrode.

The light emitting element ED may include a light emitting area EA having a predetermined size or area. The light emitting area EA of the light emitting element ED may be defined as, for example, an area in which the anode electrode AE, the emission layer EL, and the cathode electrode CE overlap one another.

The light emitting element ED may be, for example, an organic light emitting diode (OLED), an inorganic light emitting diode, a quantum dot light emitting element, or the like. In the example where an organic light emitting diode (OLED) is used as the light emitting element ED, the emission layer EL thereof may include an organic emission layer including an organic material.

The scan transistor ST can be turned on and off by a scan signal SCAN, which is a gate signal applied through a gate line GL, and be electrically connected between the first node N1 of the driving transistor DT and a data line DL.

The storage capacitor Cst may be electrically connected between the first node N1 and the second node N2 of the driving transistor DT.

The pixel circuit SPC may be configured with two transistors (2T: DRT and SCT) and one capacitor (1C: Cst) (which may be referred to as a “2T1C structure”) as shown in FIG. 3, and in one or more implementations, may further include one or more transistors, and/or further include one or more capacitors.

In one or more embodiments, the storage capacitor Cst, which may be present between the first node N1 and the second node N2 of the driving transistor DT, may be an external capacitor intentionally configured or designed to be located outside of the driving transistor DT, other than internal capacitors, such as parasitic capacitors (e.g., a gate-to-source capacitance Cgs, a gate-to-drain capacitance Cgd, and the like). Each of the driving transistor DT and the scan transistor ST may be an n-type transistor or a p-type transistor.

Since circuit elements (in particular, a light emitting element ED implemented with an organic light emitting diode including an organic material) included in each subpixel SP are vulnerable to external moisture or oxygen, an encapsulation layer ENCAP may be disposed in the display panel 110 in order to reduce or prevent external moisture or oxygen from penetrating into such circuit elements. The encapsulation layer ENCAP may be disposed such that it covers the light emitting element ED.

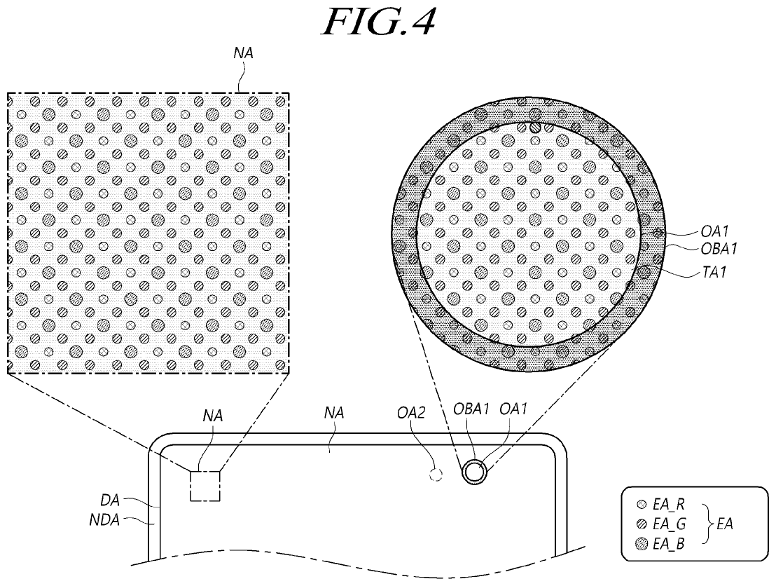

FIG. 4 schematically illustrates an example first type of optical area OA and an example normal area NA adjacent to or around the first type of optical area OA in the display panel 110 according to aspects of the present disclosure.

Referring to FIG. 4, in one or more exemplary embodiments, the display panel 110 according to aspects of the present disclosure may include a display area (e.g., the display area DA of figures described above) where one or more images can be displayed and a non-display area (e.g., the non-display area NDA of figures described above) where an image is not displayed.

Referring to FIG. 4, the display area DA may include a first optical area OA1 through which light can be transmitted, and a normal area NA adjacent to or around the optical area OA1. As an example, the normal area NA may partially surround or fully surround the optical area OA1.

The first optical area OA1 may have the structure of a first type. Thus, in an example where the optical area OA1 is implemented in the first type, a first optical bezel area OBA1 may be disposed outside of the first optical area OA1. In one or more exemplary embodiments, the first optical bezel area OBA1 may represent a part of the normal area NA.

In other words, when the first optical area OA1 is implemented in the first type, the display area DA may include the first optical area OA1, the normal area NA located outside of the first optical area OA1, and the first optical bezel area OBA1 between the first optical area OA1 and the normal area NA.

Referring to FIG. 4, the first optical area OA1 may represent an area overlapping the first optical electronic device 11, and may be, for example, a transmittable area through which light needed for the operation of the first optical electronic device 11 can be transmitted.

In an example, light passing the first optical area OA1 may include light of a single wavelength band or light of various wavelength bands. For example, the first optical area OA1 may be configured to allow, but not limited to, at least one of visible light, infrared light, ultraviolet light, and the like to be transmitted.

The first optical electronic device 11 can receive light passing through the first optical area OA1 and perform a predefined operation by using the received light. The light received by the first optical electronic device 11 through the first optical area OA1 may include at least one of visible light, infrared light, and ultraviolet light.

In an embodiment where the first optical electronic device 11 is a camera, the first optical area OA1 may be at least configured to allow visible light to be transmitted for the operation of the camera. In another embodiment where the first optical electronic device 11 is an infrared sensor based on infrared light, the first optical area OA1 may be at least configured to allow infrared light to be transmitted for the operation of the infrared sensor.

Referring to FIG. 4, the first optical bezel area OBA1 may represent an area located outside of the first optical area OA1. The normal area NA may represent an area located outside of the first optical bezel area OBA1. The first optical bezel area OBA1 may be disposed between the first optical area OA1 and the normal area NA.

For example, the first optical bezel area OBA1 may be disposed outside of only a portion of an edge of the first optical area OA1, or disposed outside of entirety of the edge of the first optical area OA1.

In the example where the first optical bezel area OBA1 is disposed outside of the entire edge of the first optical area OA1, the first optical bezel area OBA1 may have a ring shape partially or fully surrounding the first optical area OA1.

For example, the first optical area OA1 may have various shapes such as a circular shape, an elliptical shape, a polygonal shape, an irregular shape, or the like. As an example, the first optical bezel area OBA1 may have a shape corresponding to the shape of the first optical area OA1. As an example, the first optical bezel area OBA1 may have various ring shapes (e.g., a circular ring shape, an elliptical ring shape, a polygonal ring shape, an irregular ring shape, or the like) surrounding the first optical area OA1 having various shapes.

Referring to FIG. 4, the display area DA may include a plurality of light emitting areas EA. Since the first optical area OA1, the first optical bezel area OBA1, and the normal area NA are areas included in the display area DA, each of the first optical area OA1, the first optical bezel area OBA1, and the normal area NA may include a plurality of light emitting areas EA.

For example, the plurality of light emitting areas EA may include one or more first color light emitting areas emitting light of a first color, one or more second color light emitting areas emitting light of a second color, and one or more third color light emitting areas emitting light of a third color. Embodiments are not limited thereto. As an example, at least one of the first color light emitting areas, the second color light emitting areas emitting light and the third color light emitting areas could be omitted, or additional color light emitting areas emitting light of a different color may be further included.

As an example, at least one of the first color light emitting area, the second color light emitting area, and the third color light emitting area may have a different area or size from the remaining one or more light emitting areas. Embodiments are not limited thereto. As an example, the first color light emitting area, the second color light emitting area, and the third color light emitting area may have the same area or size.

The first color, the second color, and the third color may be different colors from one another, and may be various colors. For example, the first color, second color, and third color may be or include red, green, and blue, respectively.

Hereinafter, for convenience of description, the first color, the second color, and the third color are considered to be red, green, and blue, respectively. However, embodiments of the present disclosure are not limited thereto. As an example, other colors such as white, magenta, yellow, cyan, etc. are also possible.

In the example where the first color, the second color, and the third color are red, green, and blue, respectively, an area of a blue light emitting area EA_B may be greater than an area of a red light emitting area EA_R and an area of a green light emitting area EA_G, without being limited thereto.

A light emitting element ED disposed in the red light emitting area EA_R may include an emission layer EL emitting red light. A light emitting element ED disposed in the green light emitting area EA_G may include an emission layer EL emitting green light. A light emitting element ED disposed in the blue light emitting area EA_B may include an emission layer EL emitting blue light.

An organic material included in the emission layer EL emitting blue light may be more easily degraded in terms of material than respective organic materials included in the emission layer EL emitting red light and the emission layer EL emitting green light, without being limited thereto.

In one or more exemplary embodiments, as the blue light emitting area EA_B is configured or designed to have the largest area or size, current density supplied to the light emitting element ED disposed in the blue light emitting area EA_B may be the least. Therefore, a degradation degree of a light emitting element ED disposed in the blue light emitting area EA_B may be the same as or similar to a degradation degree of a light emitting element ED disposed in the red light emitting area EA_R and a degradation degree of a light emitting element ED disposed in the green light emitting area EA_G.

In consequence, a difference in degradation between the light emitting element ED disposed in the red light emitting area EA_R, the light emitting elements ED disposed in the green light emitting area EA_G, and the light emitting elements ED disposed in the blue light emitting area EA_B cannot be produced or can be reduced, and therefore, the display device 100 or the display panel 110 according to aspects of the present disclosure can provide an advantage of improving image quality. In addition, as a difference in degradation between the light emitting element ED disposed in the red light emitting area EA_R, the light emitting elements ED disposed in the green light emitting area EA_G, and the light emitting elements ED disposed in the blue light emitting area EA_B is eliminated or reduced, the display device 100 or the display panel 110 according to aspects of the present disclosure can therefore provide an advantage of reducing a difference in lifespan between the light emitting element ED disposed in the red light emitting area EA_R, the light emitting elements ED disposed in the green light emitting area EA_G, and the light emitting elements ED disposed in the blue light emitting area EA_B.

Referring to FIG. 4, the first optical area OA1 may be a transmittable area, and therefore, be required to have high transmittance. To achieve this requirement, in one or more embodiments, a cathode electrode CE (e.g., the cathode electrode in FIG. 3) may be implemented as a transparent electrode.

Referring to FIG. 4, the cathode electrode CE in the normal area NA and the first optical bezel area OBA1 may include a material different from the cathode electrode CE in the first optical area OA1. For example, the cathode electrode CE in the normal area NA and the first optical bezel area OBA1 may include a metal or a metal alloy, without being limited thereto. In this example, the cathode electrode CE may have a thin thickness and thus have translucent characteristics. As an example, the cathode electrode CE in the first optical area OA1 may have a thinner thickness as compared with that in the normal area NA and/or the first optical bezel area OBA1 and thus have translucent characteristics.

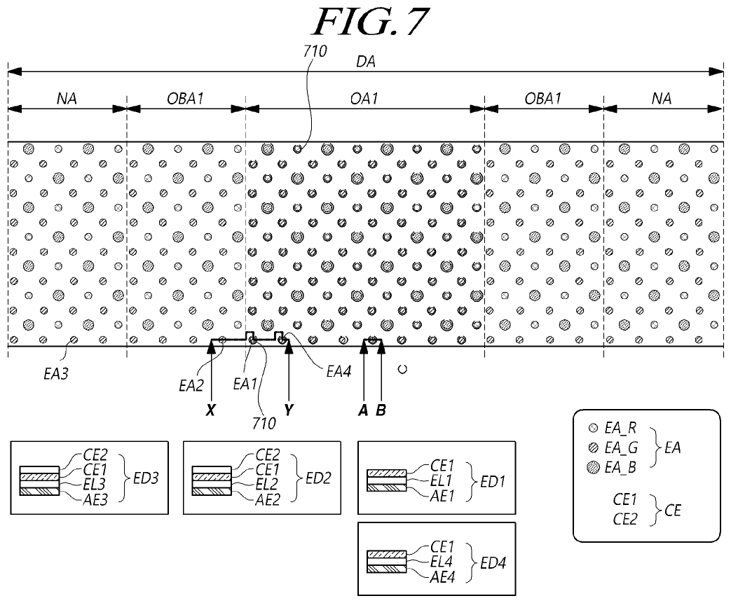

The first optical area OA1 may include one or more light emitting areas EA and one or more transmissive areas TA1. For example, the first optical area OA1 may further include a non-transmissive area. This structure will be described in detail with reference to FIG. 7.

Referring to FIG. 4, a second optical area (e.g., the second optical area OA2 in figures described above) may be disposed adjacent to the first optical area OA1. An arrangement of light emitting areas EA in the second optical area OA2 will be described in more detail later. Embodiments are not limited thereto. As an example, the second optical area may be located independently from the first optical area OA1, and may be located at any position in the display area DA.

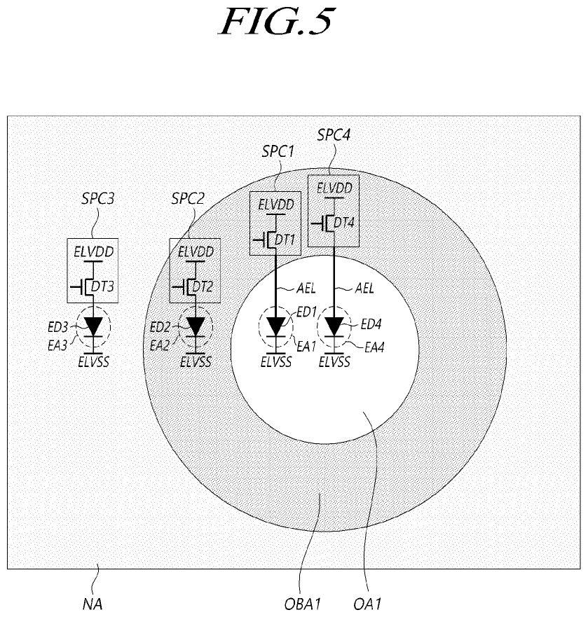

FIG. 5 illustrates an example configuration of light emitting elements and pixel circuits for driving the light emitting elements in the display panel 110 according to aspects of the present disclosure. As illustrated in FIG. 5, the display panel 110 may include light emitting elements (ED1, ED2, ED3, and ED4) disposed in the normal area NA, the first optical bezel area OBA1, and the first optical area OA1, and pixel circuits (SPC1, SPC2, SPC3, and SPC4) for driving the light emitting elements (ED1, ED2, ED3, and ED4).

It should be understood here that each of the pixel circuits (SPC1, SPC2, SPC3, and SPC4) may include transistors (DT and ST), a storage capacitor Cst, and the like as shown in FIG. 3. However, it should be noted that for convenience of explanation, each of the pixel circuits (SPC1, SPC2, SPC3, and SPC4) is simply expressed as only a respective driving transistor (DT1, DT2, DT3, and DT4).

Referring to FIG. 5, the normal area NA, the first optical area OA1, and the first optical bezel area OBA1 may have structural differences as well as positional differences.

As one example of such structural differences, one or more pixel circuits (SPC1, SPC2, SPC3, and/or SPC4) may be disposed in the first optical bezel area OBA1 and the normal area NA, but a pixel circuit may not be disposed in the first optical area OA1. For example, the first optical bezel area OBA1 and the normal area NA may be configured to allow one or more transistors (DT1, DT2, DT3, and/or DT4) to be disposed therein, and the first optical area OA1 may be configured not to allow a transistor to be present therein.

Transistors and storage capacitors included in the pixel circuits (SPC1, SPC2, SPC3, and SPC4) may be components causing transmittance to be reduced. Thus, since a pixel circuit (e.g., SPC1, SPC2, SPC3, or SPC4) is not disposed in the first optical area OA1, the transmittance of the first optical area OA1 can be more improved.

In one or more embodiments, although the pixel circuits (SPC1, SPC2, SPC3, and SPC4) may be disposed only in the normal area NA and the first optical bezel area OBA1, the light emitting elements (ED1, ED2, ED3, and ED4) may be disposed in the normal area NA, the first optical bezel area OBA1, and the first optical area OA1.

Referring to FIG. 5, although a first light emitting element ED1 may be disposed in the first optical area OA1, a first pixel circuit SPC1 for driving the first light emitting element ED1 may not be located in the first optical area OA1.

Referring to FIG. 5, the first pixel circuit SPC1 for driving the first light emitting element ED1 disposed in the first optical area OA1 may be disposed in the first optical bezel area OBA1, not in the first optical area OA1.

Hereinafter, the normal area NA, the first optical area OA1, and the first optical bezel area OBA1 will be described in more detail.

Referring to FIG. 5, in one or more exemplary embodiments, a plurality of light emitting areas EA included in the display panel 110 according to aspects of the present disclosure may include a first light emitting area EA1, a second light emitting area EA2, and a third light emitting area EA3. In these embodiments, the first light emitting area EA1, the second light emitting area EA2, and the third light emitting area EA3 may be included in the first optical area OA1, the first optical bezel area OBA1, and the normal area NA, respectively. Hereinafter, it is assumed that the first light emitting area EA1, the second light emitting area EA2, and the third light emitting area EA3 are areas emitting light of a same color. Embodiments are not limited thereto. As an example, at least one of the first light emitting area EA1, the second light emitting area EA2, and the third light emitting area EA3 are areas emitting light of a different color from the remaining areas.

Referring to FIG. 5, in one or more exemplary embodiments, the display panel 110 according to aspects of the present disclosure may include a first light emitting element ED1 disposed in the first optical area OA1 and having the first light emitting area EA1, a second light emitting element ED2 disposed in the first optical bezel area OBA1 and having the second light emitting area EA2, and a third light emitting element ED3 disposed in the normal area NA and having the third light emitting area EA3.

Referring to FIG. 5, in one or more exemplary embodiments, the display panel 110 according to aspects of the present disclosure may further include a first pixel circuit SPC1 configured to drive the first light emitting element ED1, a second pixel circuit SPC2 configured to drive the second light emitting element ED2, and a third pixel circuit SPC3 configured to drive the third light emitting element ED3.

Referring to FIG. 5, the first pixel circuit SPC1 may include a first driving transistor DT1. The second pixel circuit SPC2 may include a second driving transistor DT2. The third pixel circuit SPC3 may include a third driving transistor DT3.

Referring to FIG. 5, in one or more exemplary embodiments, in the display panel 110 according to aspects of the present disclosure, the second pixel circuit SPC2 may be located in the first optical bezel area OBAL where the second light emitting element ED2 corresponding to the second pixel circuit SPC2 is disposed, and the third pixel circuit SPC3 may be located in the normal area NA where the third light emitting element ED3 corresponding to the third pixel circuit SPC3 is disposed.

Referring to FIG. 5, in one or more exemplary embodiments, in the display panel 110 according to aspects of the present disclosure, the first pixel circuit SPC1 may not be located in the first optical area OA1 where the first light emitting element ED1 corresponding to the first pixel circuit SPC1 is disposed. Instead, the first pixel circuit SPC1 may be located in the first optical bezel area OBA1 located outside of the first optical area OA1. As a result, the transmittance of the first optical area OA1 can be improved.

Referring to FIG. 5, in one or more embodiments, the display panel 110 according to aspects of the present disclosure may further include an anode extension line AEL electrically connecting the first light emitting element EDI disposed in the first optical area OA1 to the first pixel circuit SPC1 disposed in the first optical bezel area OBA1.

The anode extension line AEL may electrically extend or connect an anode electrode AE of the first light emitting element ED1 to a second node N2 of the first driving transistor DT1 in the first pixel circuit SPC1.

As described above, in the display panel 110 according to aspects of the present disclosure, the first pixel circuit SPC1 for driving the first light emitting element ED1 disposed in the first optical area OA1 may be disposed in the first optical bezel area OBA1, not in the first optical area OA1. Such a structure may be referred to as an anode extension structure. Likewise, the first type of the first optical area OA may be also referred to as an anode extension type.

In an exemplary embodiment where the display panel 110 according to aspects of the present disclosure has such an anode extension structure, all or a portion of the anode extension line AEL may be disposed in the first optical area OA1, and/or the anode extension line AEL may include a transparent material, or be or include a transparent line. Accordingly, even when the anode extension line AEL for connecting the first pixel circuit SPC1 to the first light emitting element ED1 is disposed in the first optical area OA1, the display device or the display panel 110 according to aspects of the present disclosure can reduce or prevent the transmittance of the first optical area OA1 from being reduced.

Referring to FIG. 5, the plurality of light emitting areas EA may further include a fourth light emitting area EA4 emitting light of the same color as the first light emitting area EA1 and included in the first optical area OA1, without being limited thereto. As an example, the fourth light emitting area EA4 may emit light of a different color from the first light emitting area EA1.

Referring to FIG. 5, as an example, the fourth light emitting area EA4 may be disposed adjacent to the first light emitting area EA1. As an example, the fourth light emitting area EA4 may be disposed adjacent to the first light emitting area EA1 in a row direction or a column direction, or in a diagonal direction, without being limited thereto.

Referring to FIG. 5, in one or more exemplary embodiments, the display panel 110 according to aspects of the present disclosure may further include a fourth light emitting element ED4 disposed in the first optical area OA1 and having the fourth light emitting area EA4, and a fourth pixel circuit SPC4 configured to drive the fourth light emitting element ED4.

Referring to FIG. 5, the fourth pixel circuit SPC4 may include a fourth driving transistor DT4. For convenience of description, a scan transistor ST and a storage capacitor Cst included in the fourth pixel circuit SPC4 are omitted from FIG. 5.

Referring to FIG. 5, although the fourth pixel circuit SPC4 is a circuit for driving the fourth light emitting element ED4 disposed in the first optical area OA1, the fourth pixel circuit SPC4 may be disposed in the first optical bezel area OBA1.

Referring to FIG. 5, in one or more embodiments, the display panel 110 according to aspects of the present disclosure may further include an anode extension line AEL for electrically connecting the fourth light emitting element ED4 to the fourth pixel circuit SPC4.

All or a portion of the anode extension line AEL may be disposed in the first optical area OA1, and/or the anode extension line AEL may include a transparent material, or be or include a transparent line.

As described above, the first pixel circuit SPC1 disposed in the first optical bezel area OBA1 may be configured to drive one light emitting element ED1 disposed in the first optical area OA1. Such a circuit connection scheme may be referred to as a one-to-one (1:1) circuit connection scheme.

As a result, the number of pixel circuits SPC disposed in the first optical bezel area OBA1 may be increased significantly. Further, the structure of the first optical bezel area OBA1 may become complicated, and an open area (which may be referred to as an aperture ratio, an open ratio, or a light emitting area) of the first optical bezel area OBA1 may be reduced.

In order to increase an open area (or an aperture ratio, or an open ratio, or a light emitting area) of the first optical bezel area OBA1 while having an anode extension structure, in one or more exemplary embodiments, the display device 100 according to aspects of the present disclosure may be configured in a 1:N (where N is 2 or more) circuit connection scheme.

According to the 1:N circuit connection scheme, the first pixel circuit SPC1 disposed in the first optical bezel area OBA1 may be configured to drive two or more light emitting elements ED disposed in the first optical area OA1 concurrently or together. Embodiments are not limited thereto. As an example, the first pixel circuit SPC1 disposed in the first optical bezel area OBA1 may be configured to drive two or more light emitting elements ED disposed in the first optical area OA1 individually, for example, by including additional transistors. In this case, as an example, at least one of the additional transistors could be also disposed in the first optical bezel area OBA1.

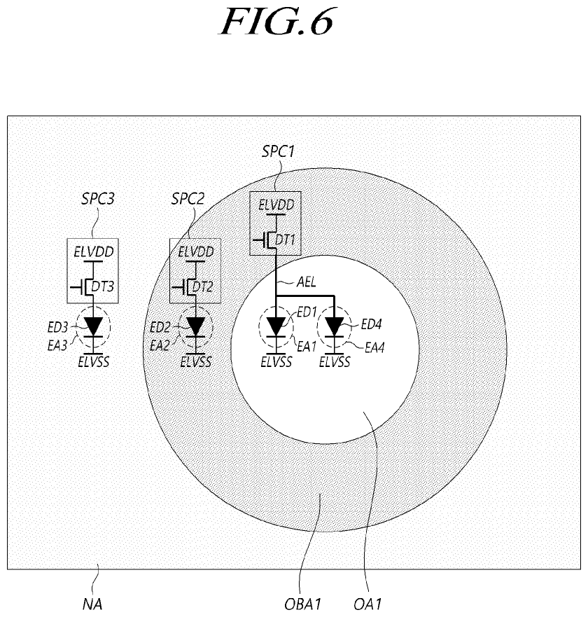

FIG. 6 illustrates a 1:2 circuit scheme as an example for convenience of description. In this example, a first pixel circuit SPC1 disposed in the first optical bezel area OBA1 may be configured to drive two light emitting elements (ED1 and ED4) disposed in the first optical area OA1 concurrently or together.

In one or more exemplary embodiments, referring to FIG. 6, light emitting elements (ED1, ED2, ED3, and ED4) disposed in the normal area NA, the first optical bezel area OBA1, and the first optical area OA1, and pixel circuits (SPC1, SPC2, and SPC3) for driving the light emitting elements (ED1, ED2, ED3, and ED4) may be disposed in the display panel 110.

Referring to FIG. 6, a fourth light emitting element ED4 disposed in the first optical area OA1 can be driven by the first pixel circuit SPC1 for driving a first light emitting element ED1 located in the first optical area OA1. That is, the first pixel circuit SPC1 disposed in the first optical bezel area OBA1 may be configured to drive the first light emitting element ED1 and the fourth light emitting element ED4 disposed in the first optical area OA1 together or substantially concurrently.

Accordingly, even when the display panel 110 has an anode extension structure, the number of pixel circuits SPC disposed in the first optical bezel area OBA1 can be significantly reduced, and thereby, an open area and a light emitting area of the first optical bezel area OBA1 can be increased.

In the example of FIG. 6, the first light emitting element ED1 and the fourth light emitting element ED4 driven together by the first pixel circuit SPC1 disposed in the first optical bezel area OBA1 may be light emitting elements that emit light of a same color. As an example, the first light emitting element ED1 and the fourth light emitting element ED4 may be adjacent to each other in a row direction or a column direction or in a diagonal direction, without being limited thereto. As an example, the first light emitting element ED1 and the fourth light emitting element ED4 may be spaced apart from each other with at least one other light emitting element interposed therebetween, and be electrically connected to each other, for example, via an anode extension line AEL.

Referring to FIG. 6, an anode extension line AEL may connect the first light emitting element ED1 and the fourth light emitting element ED4 disposed in the first optical area OA1 to the first pixel circuit SPC1 disposed in the first optical bezel area OBA1.

FIG. 7 is an example plan view of the normal area NA, the first optical bezel area OBA1, and the first optical area OA1 in the display panel 110 according to aspects of the present disclosure.

Referring to FIG. 7, in one or more exemplary embodiments, in the display panel 110 according to aspects of the present disclosure, a plurality of light emitting areas EA disposed in each of the normal area NA, the first optical bezel area OBA1, and the first optical area OA1 may include one or more red light emitting areas EA_R, one or more green light emitting areas EA_G, and one or more blue light emitting areas EA_B.

Referring to FIG. 7, in one or more exemplary embodiments, in the display panel 110 according to aspects of the present disclosure, a cathode electrode (e.g., the cathode electrode CE of FIG. 3) may be disposed in the normal area NA, the first optical bezel area OBA1, and the first optical area OA1.

For example, the cathode electrode may include a first cathode electrode CE1 and a second cathode electrode CE2. In this example, the first cathode electrode CE1 may be disposed in the first optical area OA1, and the first cathode electrode CE1 and the second cathode electrode CE2 may be disposed in the first optical bezel area OBA1 and the normal area NA. That is, the second cathode electrode CE2 may be disposed only in the first optical bezel area OBA1 and the normal area NA. Embodiments are not limited thereto. As an example, the first cathode electrode CE1 may be disposed in the first optical area OA1, and the second cathode electrode CE2 may be disposed in the first optical bezel area OBA1 and the normal area NA.

The first cathode electrode CE1 and the second cathode electrode CE2 may have different transmittances. For example, the first cathode electrode CE1 may include a transparent electrode material, and the second cathode electrode CE2 may include a metal or a metal alloy. As an example, the second cathode electrode CE2 may have a thin thickness to improve transmittance, without being limited thereto. Thereby, the second cathode electrode CE2 can help light emitted from corresponding one or more light emitting elements ED direct toward the outside of the display panel 110 or the display device 100.

However, one or more cathode electrodes included in the first to fourth light emitting elements (ED1, ED2, ED3, and ED4) in the display panel 110 according to aspects of the present disclosure are not limited to the foregoing configuration. For example, a cathode electrode including at least a transparent conductive material may be sufficient to be disposed in the first optical area OA1, and a cathode electrode including at least a metal or metal alloy may be sufficient to be disposed in the normal area NA and the first optical bezel area OBA1.

In this configuration, transmittance in the first optical area OA1 may be higher than transmittance in the first optical bezel area OBA1 and the normal area NA.

In one or more exemplary embodiments, the first optical area OA1 may be configured such that all of the remaining first optical area OA1 except for an area where one or more light path changing elements 710 are disposed allows light to be transmitted. Further, the first optical area OA1 may be configured such that the remaining first optical area OA1 except for light emitting areas EA and the area where the one or more light path changing elements 710 are disposed is configured to allow light to be transmitted better.

As an example, in the first optical area OA1, the area where one or more light path changing elements 710 are disposed may be a non-transmissive area, and the remaining first optical area OA1 may be a transmissive area.

In one or more embodiments, referring to FIG. 7, in the first optical area OA1, one or more light path changing elements 710 may be disposed such that each of the light path changing elements 710 or each portion of the one light path changing element 710 surrounds a respective one of the light emitting areas EA. For example, each of the light path changing elements 710 or each portion of the one light path changing element 710 may expose at least one side of a respective one of the light emitting areas EA while surrounding the respective one of the light emitting areas EA. Hereinafter, for convenience of discussions, it is assumed that one light path changing element 710 is disposed in the first optical area OA1 such that each portion of the one light path changing element 710 is disposed in each light emitting area EA. This is merely for convenience of discussions, and thus, the scope of the present disclosure includes examples where each of light path changing elements 710 is disposed in a respective one of light emitting areas EA.

In these embodiments, anode electrodes (e.g., AE1 and AE4) disposed in the first optical area OA1 may be spaced apart from the light path changing element 710. Thereby, the anode electrodes (e.g., AE1 and AE4) can extend to the first optical bezel area OBA1, as well as the first optical area OA1, without an interference of the light path changing element 710.

In the first optical area OA1, the first cathode electrode CE1 may be disposed in light emitting areas and a non-light emitting area. For example, the first cathode electrode CE1 may be disposed in the entire first optical area OA1. Embodiments are not limited thereto. As an example, the first cathode electrode CE1 may be disposed only in the light emitting areas. As an example, the first cathode electrode CE1 may be disposed in light emitting areas and a portion of the non-light emitting area.

Referring to FIG. 7, an arrangement of light emitting areas EA in the first optical area OA1, an arrangement of light emitting areas EA in the first optical bezel area OBA1, and an arrangement of light emitting areas EA in the normal area NA may be the same as one another, without being limited thereto.

Referring to FIG. 7, a plurality of light emitting areas EA may include first light emitting areas EA1 included in the first optical area OA1, second light emitting areas EA2 included in the first optical bezel area OBA1, and third light emitting areas EA3 included in the normal area NA. As an example, the second light emitting areas EA2 and/or the third light emitting areas EA3 may emit light of the same color as the first light emitting areas EA1, without being limited thereto. As an example, the second light emitting areas EA2 and/or the third light emitting areas EA3 may emit a different light from the first light emitting areas EA1.

Referring to FIG. 7, the plurality of light emitting areas EA may further include fourth light emitting areas EA4 included in the first optical area OA1. As an example, the fourth light emitting areas EA4 may emit light of the same color as or different color from the first light emitting areas EA1.

Referring to FIG. 7, in one or more embodiments, the display panel 110 according to aspects of the present disclosure may include first anode electrodes AE1 disposed in the first optical area OA1, second anode electrodes AE2 disposed in the first optical bezel area OBA1, third anode electrodes AE3 disposed in the normal area NA, and fourth anode electrodes AE4 disposed in the first optical area OA1.

In one or more embodiments, the display panel 110 according to aspects of the present disclosure may include first emission layers EL1 disposed in the first optical area OA1, second emission layers EL2 disposed in the first optical bezel area OBA1, third emission layers EL3 disposed in the normal area NA, and fourth emission layers EL4 disposed in the first optical area OA1.

As an example, the first to fourth emission layers EL4 may be emission layers emitting light of a same color. In these embodiments, the first to fourth emission layers EL1 to EL4 may be disposed as separate emission layers or be integrated into a single emission layer.

Referring to FIG. 7, light emitting elements of the display panel 110 according to aspects of the present disclosure may be configured such that: each of the first light emitting elements ED1 is configured with the first anode electrode AE1, the first emission layer EL1, and the first cathode electrode CE1; each of the second light emitting elements ED2 is configured with the second anode electrode AE2, the second emission layer EL2, the first cathode electrode CE1, and the second cathode electrode CE2; each of the third light emitting elements ED3 is configured with the third anode electrode AE3, the third emission layer EL3, the first cathode electrode CE1, and the second cathode electrode CE2; and each of the fourth light emitting elements ED4 is configured with the fourth anode electrode AE4, the fourth emission layer EL4, and the first cathode electrode CE1.

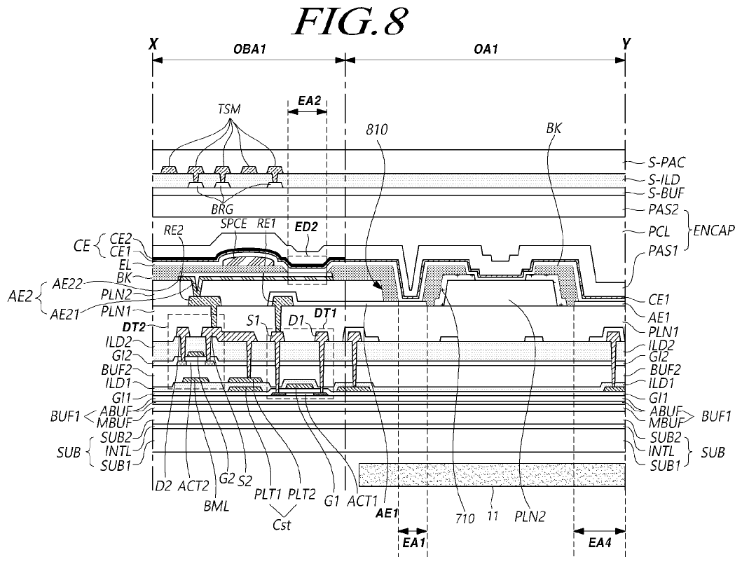

Hereinafter, an example cross-sectional structure taken along line X-Y of FIG. 7 will be discussed in more detail with reference to FIGS. 8 to 11.

A portion indicated by line X-Y in FIG. 7 includes a portion of the first optical bezel area OBA1 and a portion of the first optical area OA1 with respect to a boundary between the first optical bezel area OBA1 and the first optical area OA1.

The portion indicated by line X-Y in FIG. 7 may include the first light emitting area EA1 and the fourth light emitting area EA4 included in the first optical area OA1, and the second light emitting area EA2 included in the first optical bezel area OBA1. The first light emitting area EA1, the fourth light emitting area EA4, and the second light emitting area EA2 may represent light emitting areas EA emitting light of a same color.

FIG. 8 illustrates an example cross-sectional view of the display panel 110 according to aspects of the present disclosure, and more specifically, illustrates example cross-sectional views in the first optical bezel area OBA1 and the first optical area OA1 of the display panel 110. FIG. 8 is an example cross-sectional view taken along line X-Y of FIG. 7.

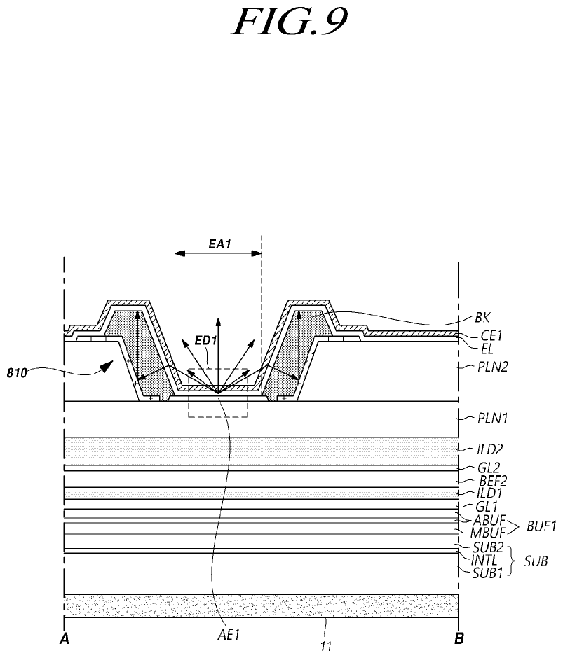

FIG. 9 is an example cross-sectional view of the display panel 110 according to aspects of the present disclosure, and represents a portion of the first optical area OA1 of the display panel 110. FIG. 9 is an example cross-sectional view taken along line A-B of FIG. 7.

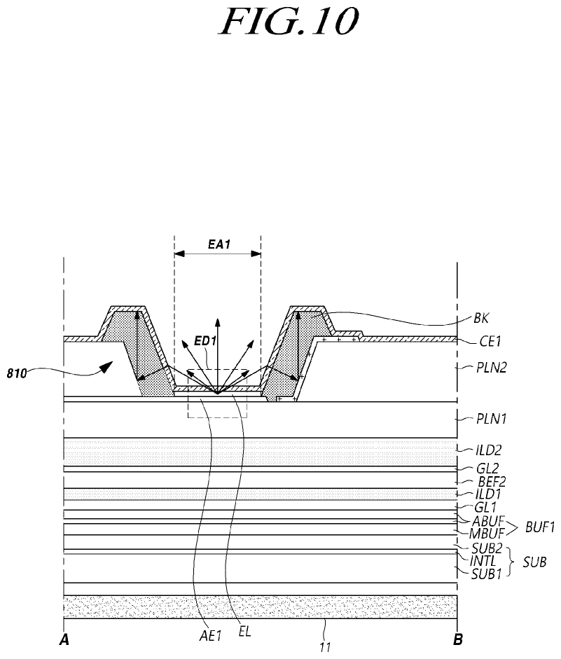

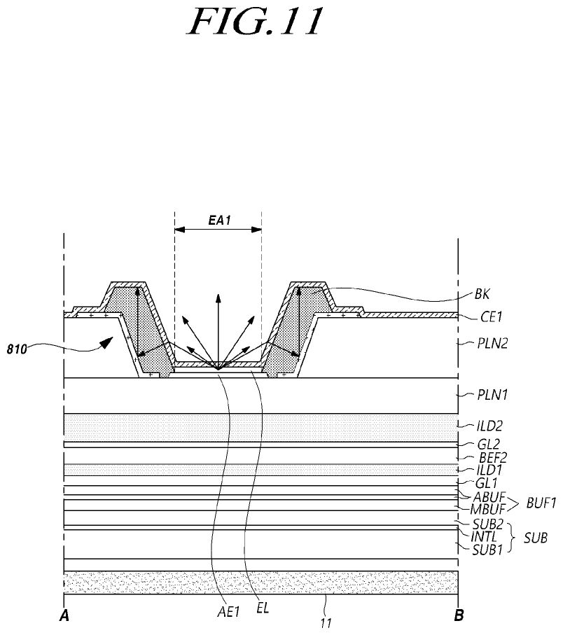

FIGS. 10 and 11 are example cross-sectional views of the display panel 110 according to aspects of the present disclosure, and illustrate example structures capable of reducing or preventing a voltage drop through a contact between an emission layer and a first cathode electrode of a light emitting element.

It should be noted here that FIGS. 8 to 11 illustrates cross-sectional views based on the application of the 1:1 circuit connection scheme, as in FIG. 5.

Referring to FIG. 8, in terms of stack up configuration, the display panel 110 may include a transistor forming part, a light emitting element forming part, and an encapsulation part.

The transistor forming part may include a substrate SUB, a first buffer layer BUF1 on the substrate SUB, various types of transistors DT1 and DT2 formed on the first buffer layer BUF, a storage capacitor Cst, and various electrodes and signal lines.

The substrate SUB may include, for example, a first substrate SUB1 and a second substrate SUB2, and may include an intermediate layer INTL interposed between the first substrate SUB1 and the second substrate SUB2. In this example, the intermediate layer INTL may be an inorganic layer and can serve to reduce or prevent moisture permeation. Embodiments are not limited thereto. As an example, the substrate SUB may include a single substrate without an intermediate layer, or more substrates and intermediate layers.

The first buffer layer BUF1 may include a stack of a single layer or a stack of a multilayer. In an example where the first buffer layer BUF1 includes a stack of a multilayer, the first buffer layer BUF1 may include a multi-buffer layer MBUF and an active buffer layer ABUF.

Various types of transistors (DT1, DT2, and the like), at least one storage capacitor Cst, and various electrodes or signal lines may be disposed on the first buffer layer BUF1.

For example, the transistors DT1 and DT2 formed on the first buffer layer BUF1 may include a same material, and/or be located in one or more same layers. In another example, as shown in FIG. 8, a first driving transistor DT1 and a second driving transistor DT2 among the transistors (DT1, DT2, and the like) may include different materials and/or be located in different layers.

Referring to FIG. 8, the first driving transistor DT1 may represent a driving transistor DT for driving the first light emitting element ED1 included in the first optical area OA1, and the second driving transistor DT2 may represent a driving transistor DT for driving the second light emitting element ED2 included in the first optical bezel area OBA1.

For example, the first driving transistor DT1 may represent a driving transistor included in the first pixel circuit SPC1 for driving the first light emitting element ED1 included in the first optical area OA1, and the second driving transistor DT2 may represent a driving transistor included in the second pixel circuit SPC2 for driving the second light emitting element ED2 included in the first optical bezel area OBA1.

Stack up configurations of the first driving transistor DT1 and the second driving transistor DT2 will be described below.

The first driving transistor DT1 may include a first active layer ACT1, a first gate electrode G1, a first source electrode S1, and a first drain electrode D1.

The second driving transistor DT2 may include a second active layer ACT2, a second gate electrode G2, a second source electrode S2, and a second drain electrode D2.

The second active layer ACT2 of the second driving transistor DT2 may be located in a higher location in the stack up configuration than the first active layer ACT1 of the first driving transistor DT1. Embodiments are not limited thereto. As an example, the second active layer ACT2 of the second driving transistor DT2 may be located in a lower location in the stack up configuration than the first active layer ACT1 of the first driving transistor DT1, or on the same layer as the first active layer ACT1 of the first driving transistor DT1.

The first buffer layer BUF1 may be disposed under the first active layer ACT1 of the first driving transistor DT1, and the second buffer layer BUF2 may be disposed under the second active layer ACT2 of the second driving transistor DT2.

For example, the first active layer ACT1 of the first driving transistor DT1 may be located on the first buffer layer BUF1, and the second active layer ACT2 of the second driving transistor DT2 may be located on the second buffer layer BUF2. In this case, the second buffer layer BUF2 may be placed in a higher location than the first buffer layer BUF.

The first active layer ACT1 of the first driving transistor DT1 may be disposed on the first buffer layer BUF1, and a first gate insulating layer GI1 may be disposed on the first active layer ACT1 of the first driving transistor DT1. The first gate electrode G1 of the first driving transistor DT1 may be disposed on the first gate insulating layer GI1, and a first interlayer insulating layer ILD1 may be disposed on the first gate electrode G1 of the first driving transistor DT1.

In this implementation, the first active layer ACT1 of the first driving transistor DT1 may include a first channel region overlapping the first gate electrode G1, a first source connection region located on one side of the first channel region, and a first drain connection region located on the other side of the first channel region.

The second buffer layer BUF2 may be disposed on the first interlayer insulating layer ILD1.

The second active layer ACT2 of the second driving transistor DT2 may be disposed on the second buffer layer BUF2, and a second gate insulating layer GI2 may be disposed on the second active layer ACT2. The second gate electrode G2 of the second driving transistor DT2 may be disposed on the second gate insulating layer GI2, and a second interlayer insulating layer ILD2 may be disposed on the second gate electrode G2.

In this implementation, the second active layer ACT2 of the second driving transistor DT2 may include a second channel region overlapping the second gate electrode G2, a second source connection region located on one side of the second channel region, and a second drain connection region located on the other side of the second channel region.

The first source electrode S1 and the first drain electrode D1 of the first driving transistor DT1 may be disposed on the second interlayer insulating layer ILD2. The second source electrode S2 and the second drain electrode D2 of the second driving transistor DT2 may be also disposed on the second interlayer insulating layer ILD2. Embodiments are not limited thereto. As an example, at least one of the first source electrode S1 and the first drain electrode D1 of the first driving transistor DT1 and the second source electrode S2 and the second drain electrode D2 of the second driving transistor DT2 may be disposed on a different layer.

The first source electrode S1 and the first drain electrode D1 of the first driving transistor DT1 may be respectively connected to the first source connection region and the first drain connection region of the first active layer ACT1 through through-holes formed in the second interlayer insulating layer ILD2, the second gate insulating layer GI2, the second buffer layer BUF2, the first interlayer insulating layer ILD1, and the first gate insulating layer GI1.

The second source electrode S2 and the second drain electrode D2 of the second driving transistor DT2 may be respectively connected to the second source connection region and the second drain connection region of the second active layer ACT2 through through-holes formed in the second interlayer insulating layer ILD2 and the second gate insulating layer GI2.

It should be understood that FIG. 8 illustrates only the second driving transistor DT2 and a storage capacitor Cst among circuit components included in the second pixel circuit SPC2, and other components such as one or more transistors, and the like are omitted. It should be also understood that FIG. 8 illustrates only the first driving transistor DT1 among circuit components included in the first pixel circuit SPC1, and other components such as one or more transistors, a storage capacitor, and the like are omitted.

Referring to FIG. 8, the storage capacitor Cst included in the second pixel circuit SPC2 may include a first capacitor electrode PLT1 and a second capacitor electrode PLT2.

The first capacitor electrode PLT1 may be electrically connected to the second gate electrode G2 of the second driving transistor DT2, and the second capacitor electrode PLT2 may be electrically connected to the second source electrode S2 of the second driving transistor DT2.

In one or more exemplary embodiments, referring to FIG. 8, a lower metal BML may be optionally disposed under the second active layer ACT2 of the second driving transistor DT2. This lower metal BML may overlap all or at least a portion of the second active layer ACT2.

As an example, the lower metal BML may be electrically connected to, for example, the second gate electrode G2. In another example, the lower metal BML can serve as a light shield for shielding light traveling from a lower location than the lower metal BML. In this implementation, the lower metal BML may be electrically connected to the second source electrode S2. As an example, the lower metal BML may be omitted depending on the design.

Even though the first driving transistor DT1 is a transistor for driving the first light emitting element ED1 disposed in the first optical area OA1, the first driving transistor DT1 may be disposed in the first optical bezel area OBA1.

As the second driving transistor DT2 is a transistor for driving the second light emitting element ED2 disposed in the first optical bezel area OBA1, the second driving transistor DT2 may be disposed in the first optical bezel area OBA1.

Referring to FIG. 8, a first planarization layer PLN1 may be disposed on the first driving transistor DT1 and the second driving transistor DT2. For example, the first planarization layer PLN1 may be disposed on the first source electrode S1 and the first drain electrode D1 of the first driving transistor DT1 and the second source electrode S2 and the second drain electrode D2 of the second driving transistor DT2.

Referring to FIG. 8, a first relay electrode RE1 and a second relay electrode RE2 may be disposed on the first planarization layer PLN1.

The first relay electrode RE1 may represent an electrode for relaying an electrical connection between the first source electrode S1 of the first driving transistor DT1 and the first anode electrode AE1 of the first light emitting element ED1. The second relay electrode RE2 may represent an electrode for relaying an electrical connection between the second source electrode S2 of the second driving transistor DT2 and the second anode electrode AE2 of the second light emitting element ED2.

The first relay electrode RE1 may be electrically connected to the first source electrode S1 of the first driving transistor DT1 through a hole formed in the first planarization layer PLN1. The second relay electrode RE2 may be electrically connected to the second source electrode S2 of the second driving transistor DT2 through another hole formed in the first planarization layer PLN1.

Referring to FIG. 8, the first relay electrode REI and the second relay electrode RE2 may be disposed in the first optical bezel area OBA1.

Referring to FIG. 8, the first anode electrode AE1 (or an anode extension line) may be connected to the first relay electrode REI to extend from the first optical bezel area OBA1 to the first optical area OA1. As an example, the fourth anode electrode AE4 (or another anode extension line) may be also connected to another first relay electrode RE1 disposed over the substrate SUB to extend from the first optical bezel area OBAL to the first optical area OA1, without being limited thereto.

Although FIG. 8 illustrates the structure in which the first anode electrode AE1 extends from the first optical bezel area OBA1 to the first optical area OA1, structures according to embodiments of the present disclosure are not limited thereto. For example, an anode extension line contacting the first relay electrode RE1 may be disposed such that the anode extension line extends from the first optical bezel area OBA1 to the first optical area OA1, and contacts the first anode electrode AE1 in the first optical area OA1.

Referring to FIG. 8, the first anode electrode AE1 may be a metal layer disposed on the first relay electrode RE1. As an example, the first anode electrode AE1 may include a transparent material.

Referring to FIG. 8, the light emitting element forming part may be located on a second planarization layer PLN2 (or an insulating layer).

Referring to FIGS. 7 and 8, the light emitting element forming part may include the first light emitting element ED1, the second light emitting element ED2, and the fourth light emitting element ED4 disposed on the second planarization layer PLN2.

Referring to FIGS. 7 and 8, the first light emitting element ED1 and the fourth light emitting element ED4 may be disposed in the first optical area OA1, and the second light emitting element ED2 may be disposed in the first optical bezel area OBA1.

In the example of FIGS. 7 and 8, the first light emitting element ED1, the second light emitting element ED2, and the fourth light emitting element ED4 may be light emitting elements emitting light of a same color. Embodiments are not limited thereto. Respective emission layers EL of the first light emitting element ED1, the second light emitting element ED2, and the fourth light emitting element ED4 may be formed independently of one another. However, in discussions that follow, for convenience of explanation, it is assumed that respective emission layers EL of the first light emitting element ED1, the second light emitting element ED2, and the fourth light emitting element ED4 are commonly formed as one common emission layer.

Referring to FIGS. 7 and 8, the first light emitting element ED1 may be configured (i.e., made up) in an area where the first anode electrode AE1, the emission layer EL, and the first cathode electrode CE1 overlap one another. The second light emitting element ED2 may be configured (i.e., made up) in an area where the second anode electrode AE2, the emission layer EL, the first cathode electrode CE1, and the second cathode electrode CE2 overlap one another. The fourth light emitting element ED4 may be configured (i.e., made up) in an area where the fourth anode electrode AE4, the emission layer EL, and the first cathode electrode CE1 overlap one another.

Referring to FIG. 8, the first anode electrode AE1, the fourth anode electrode AE4, and the second anode electrode AE2 may have different structures. Embodiments are not limited thereto. As an example, the first anode electrode AE1, the fourth anode electrode AE4, and the second anode electrode AE2 may have the same structure.

For example, as shown in FIG. 8, the first anode electrode AE1 and the fourth anode electrode AE4 may include a stack of a single layer, and the second anode electrode AE2 may include a stack of a multilayer. Embodiments are not limited thereto. As an example, the second anode electrode AE2 may also include a stack of a single layer.

For example, each of the first anode electrode AE1 and the fourth anode electrode AE4 may include a transparent conductive material. For example, the first anode electrode AE1 and the fourth anode electrode AE4 may include at least one of indium tin oxide (ITO), indium zinc oxide (IZO), and indium gallium zinc oxide (IGZO), but embodiments of the present disclosure are not limited thereto.

The second anode electrode AE2 may include a reflective electrode AE21 and a transparent conductive material layer AE22 disposed on the reflective electrode AE21. Embodiments are not limited thereto. As an example, the second anode electrode AE2 may include only a reflective electrode or a transparent conductive material layer.

The reflective electrode AE21 may include a conductive material capable of reflecting light. For example, the reflective electrode AE21 may include any one of either a metal such as aluminum (Al), gold (Au), silver (Ag), copper (Cu), tungsten (W), molybdenum (Mo), chromium (Cr), tantalum (Ta), titanium (Ti), or the like, or an alloy thereof; however, embodiments of the present disclosure are not limited thereto.

For example, the transparent conductive material layer AE22 may include at least one of indium tin oxide (ITO), indium zinc oxide (IZO), and indium gallium zinc oxide (IGZO), but embodiments of the present disclosure are not limited thereto.

Although FIG. 8 illustrates the structure in which the second anode electrode AE2 includes a stack of double layers, embodiments of the present disclosure are not limited thereto. For example, the second anode electrode AE2 may include a stack of three or more layers.

Although not shown in FIG. 8, a structure of the third anode electrode AE3 may be the same as that of the second anode electrode AE2. Embodiments are not limited thereto. As an example, a structure of the third anode electrode AE3 may be different from that of the second anode electrode AE2.

Referring to FIG. 8, the second anode electrode AE2 may be disposed on the second planarization layer PLN2. The second anode electrode AE2 may be connected to the second relay electrode RE2 through a hole formed in the second planarization layer PLN2.

The first anode electrode AE1 may be disposed on the first planarization layer PLN1 and connected to the first relay electrode RE1.

Structures of the first anode electrode AE1 and the second anode electrode AE2 of the display panel 110 according to embodiments of the present disclosure are not limited thereto. For example, the second anode electrode AE2 may be disposed on the first planarization layer PLN1.

As an example, the first anode electrode AE1 and the second anode electrode AE2 may be disposed on a same layer or may be disposed on different layers. Further, as an example, a location of the first anode electrode AE1 may be the same as or different from that of the fourth anode electrode AE4, and a location of the second anode electrode AE2 may be the same as or different from that of the third anode electrode AE3.

Referring to FIG. 8, the second planarization layer PLN2 may include at least one concave portion 810 disposed on a respective portion of at least one of the upper surface of the first anode electrode AE1 and the upper surface of the fourth anode electrode AE4.

The at least one concave portion 810 of the second planarization layer PLN2 may expose a respective portion of at least one of the upper surface of the first anode electrode AE1 and the upper surface of the fourth anode electrode AE4.

In one or more exemplary embodiments, referring to FIGS. 8 and 9, due to the at least one concave portion 810 of the second planarization layer PLN2, at least one side edge of the first anode electrode AE1 and at least one side edge of the fourth anode electrode AE4 may not overlap the second planarization layer PLN2. Accordingly, the second planarization layer PLN2 may be spaced apart from at least one side surface of the first anode electrode AE1 and at least one side surface of the fourth anode electrode AE4.

The concave portion 810 of the second planarization layer PLN2 may be a different configuration from a contact hole through which an electrode disposed on the second planarization layer PLN2 contacts another electrode disposed under the second planarization layer PLN2.

At least a portion of the concave portion 810 of the second planarization layer PLN2 may correspond to at least one light emitting area disposed in in the display panel 110. For example, at least a portion of the concave portion 810 of the second planarization layer PLN2 may correspond to at least one of the first light emitting area EA1 and the fourth light emitting area EA4.

Referring to FIGS. 8 and 9, an optical path changing element 710 may be disposed on at least a portion of at least one side surface of the second planarization layer PLN2 in an area where the concave portion 810 is provided in the second planarization layer PLN2.

The light path changing element 710 may include a conductive material capable of reflecting light. For example, the light path changing element 710 may include any one of either a metal such as aluminum (Al), gold (Au), silver (Ag), copper (Cu), tungsten (W), molybdenum (Mo), chromium (Cr), tantalum (Ta), titanium (Ti), or the like, or an alloy thereof, but embodiments of the present disclosure are not limited thereto.

Referring to FIGS. 8 and 9, the light path changing element 710 may be disposed on a portion of the upper surface of the second planarization layer PLN2, a portion of at least one side surface of the second planarization layer PLN2, and a portion of the upper surface of the first planarization layer PLN1.

For example, referring to FIGS. 8 and 9, the light path changing element 710 may be disposed on at least a portion of the upper surface of the first planarization layer PLN1 located in at least one area in which the second planarization layer PLN2 is spaced apart from a respective side surface of at least one of the first anode electrode AE1 and the fourth anode electrode AE4 due to the concave portion 810, and be disposed on at least one side surface of the second planarization layer PLN2 corresponding to the concave portion 810, and further extend to a portion of the upper surface of the second planarization layer PLN2.

In one or more embodiments, the light path changing element 710 may not be disposed on the upper surface of the first planarization layer PLN1. In these embodiments, the light path changing element 710 may be disposed on a portion of at least one side surface of the second planarization layer PLN2 defining the concave portion 810, and a portion of the upper surface of the second planarization layer PLN2.

The light path changing element 710 may be spaced apart from anode electrodes (e.g., first and fourth anode electrodes AE1 and AE4) disposed in the first optical area OA1.

Referring to FIGS. 8 and 9, a bank BK may be disposed over a portion of the substrate SUB in which the first to fourth anode electrodes (AE1, AE2, AE3, and AE4) and the second planarization layer PLN2 are disposed.

The bank BK may be disposed on portions of respective upper surfaces of the first to fourth anode electrodes (AE1, AE2, AE3, and AE4).

Referring to FIGS. 8 and 9, the bank BK may include a plurality of bank holes, and respective portions of the first anode electrode AE1, the second anode electrode AE2, and the fourth anode electrode AE4 may be exposed through respective bank holes. That is, the plurality of bank holes formed in the bank BK may respectively overlap the respective portions of the first anode electrode AE1, the second anode electrode AE2, and the fourth anode electrode AE4.

In one or more exemplary embodiments, referring to FIGS. 8 and 9, the bank BK may also be disposed on a portion of the upper surface of the light path changing element 710. For example, the bank BK may be disposed to expose a portion of the upper surface of the optical path changing element 710 disposed on the second planarization layer PLN2.

Referring to FIGS. 8 and 9, the emission layer EL may be disposed on the bank BK. The emission layer EL may contact a portion of the first anode electrode AE1, a portion of the second anode electrode AE2, and a portion of the fourth anode electrode AE4 through the plurality of bank holes.

Referring to FIG. 8, at least one spacer SPCE may be present between the emission layer EL and the bank BK.

Referring to FIGS. 8 and 9, the cathode electrode CE may be disposed on the emission layer EL.

For example, referring to FIG. 8, only the first cathode electrode CE1 may be disposed in the first optical area OA1, and the first cathode electrode CE1 and the second cathode electrode CE2 disposed on the first cathode electrode CE1 may be disposed in the first optical bezel area OBA1 and the normal area NA. Embodiments are not limited thereto. As an example, the second cathode electrode CE2 may be further disposed in the first optical area OA1, or may be omitted from at least one of the first optical bezel area OBA1 and the normal area NA.

The first cathode electrode CE1 may include a transparent conductive material. For example, the first cathode electrode CE1 may include at least one of indium tin oxide (ITO), indium zinc oxide (IZO), and indium gallium zinc oxide (IGZO), but embodiments of the present disclosure are not limited thereto.

The second cathode electrode CE2 may include a metal material. For example, the second cathode electrode CE2 may include a translucent metal such as magnesium (Mg), silver (Ag), an alloy of magnesium and silver, or the like. The second cathode electrode CE2 may have a thin thickness to improve transmittance, and the thickness of the second cathode electrode CE2 may be less than that of the reflective electrode AE21. Embodiments are not limited thereto. As an example, the thickness of the second cathode electrode CE2 may be equal to or even greater than that of the reflective electrode AE21.

Referring to FIGS. 8 and 9, the encapsulation part may be located on the cathode electrode CE. The encapsulation part may include an encapsulation layer ENCAP formed on the cathode electrode CE (or the first cathode electrode).

Referring to FIGS. 8 and 9, the encapsulation layer ENCAP can serve to reduce or prevent penetration of moisture or oxygen into the light emitting elements (ED1, ED2, and ED4) disposed under the encapsulation layer ENCAP. In particular, the encapsulation layer ENCAP may include an organic material or film and can serve to reduce or prevent penetration of moisture or oxygen into the emission layer EL. In one or more exemplary embodiments, the encapsulation layer ENCAP may include a stack of a single layer or a stack of a multilayer.

Referring to FIGS. 8 and 9, the encapsulation layer ENCAP may include a first encapsulation layer PAS1, a second encapsulation layer PCL, and a third encapsulation layer PAS2. First encapsulation layer PAS1 and the third encapsulation layer PAS2 may be, for example, inorganic material layers, and the second encapsulation layer PCL may be, for example, an organic material layer, without being limited thereto.

Since the second encapsulation layer PCL is implemented using an organic material, the second encapsulation layer PCL can serve as a planarization layer.

In one or more exemplary embodiments, a touch sensor may be integrated into the display panel 110 according to aspects of the present disclosure. In these embodiments, the display panel 110 according to aspects of the present disclosure may include a touch sensor part including one or more touch sensors and disposed on the encapsulation layer ENCAP. As an example, the touch sensor may be omitted depending on the design.

Referring to FIG. 8, the touch sensor part may include touch sensor metals TSM and one or more bridge metals BRG, and may further include one or more insulating layers such as a sensor buffer layer S-BUF, a sensor interlayer insulating layer S-ILD, a sensor protective layer S-PAC, and the like.

The sensor buffer layer S-BUF may be disposed on the encapsulation layer ENCAP. The one or more bridge metals BRG may be disposed on the sensor buffer layer S-BUF, and the sensor interlayer insulating layer S-ILD may be disposed on the one or more bridge metals BRG.

The touch sensor metals TSM may be disposed on the sensor interlayer insulating layer S-ILD. A respective portion of each or at least one of the touch sensor metals TSM may be connected to a corresponding bridge metal BRG through a hole in the sensor interlayer insulating layer S-ILD.

Referring to FIG. 8, the touch sensor metals TSM and the one or more bridge metals BRG may be disposed in the first optical bezel area OBA1. The touch sensor metals TSM and the one or more bridge metals BRG may be disposed not to overlap the second light emitting area EA2 of the first optical bezel area OBA1. Embodiments are not limited thereto. As an example, the touch sensor metals TSM and the one or more bridge metals BRG may be disposed to overlap at least a portion of the second light emitting area EA2 of the first optical bezel area OBA1. As an example, the touch sensor metals TSM and the one or more bridge metals BRG may be formed by an opaque material or a transparent material.

A plurality of touch sensor metals TSM may be configured as one touch electrode (or one touch electrode line). For example, the plurality of touch sensor metals TSM may be arranged in a mesh pattern and therefore electrically connected to one another. One or more of the touch sensor metals TSM and the remaining one or more touch sensor metals TSM may be electrically connected through one or more respective bridge metals BRG, and thereby, be configured as one touch electrode (or one touch electrode line).

The sensor protective layer S-PAC may be disposed such that it covers the touch sensor metals TSM and the one or more bridge metals BRG.

In an exemplary embodiment where one or more touch sensors are integrated into the display panel 110, at least one of the touch sensor metals TSM, or at least a portion of at least one of the touch sensor metals TSM, located on the encapsulation layer ENCAP may extend along an inclined surface formed in an edge of the encapsulation layer ENCAP, and be electrically connected to a pad located in an edge of the display panel 110 that is further away from the inclined surface of the edge of the encapsulation layer ENCAP. The pad may be disposed in the non-display area NDA and may be a metal pattern to which the touch driving circuit 260 is electrically connected, without being limited thereto.

Meanwhile, FIGS. 8 and 9 illustrate the structure in which the emission layers EL of the light emitting elements ED are disposed on the bank BK, but embodiments of the present disclosure are not limited thereto.

As shown in FIGS. 10 and 11, for example, an emission layer EL (e.g., the emission layer of the first light emitting element ED1) may be disposed only on a corresponding anode electrode (e.g., the first anode electrode AE1) exposed by the bank BK.

In an example, a portion of the light path changing element 710 disposed on the second planarization layer PLN2 may not overlap the bank BK and the emission layer EL.

Referring to FIGS. 10 and 11, the first cathode electrode CE1 may be disposed on the portion of the light path changing element 710 disposed on the second planarization layer PLN2 that does not overlap the bank BK and the emission layer EL, this enabling the light path changing element 710 and the first cathode electrode CE1 to contact.

The first cathode electrode CE1 may have a large area to be disposed in the first optical area OA1, the first optical bezel area OBA1, and the normal area NA. This configuration may cause a cathode electrode voltage drop (IR Drop).

In the display panel 110 according to the exemplary embodiments of the present disclosure, since the first cathode electrode CE1 contacts the light path changing element 710 including a metal material, such voltage drop can be prevented or reduced.

Referring to FIGS. 8 to 11, a part of light emitted from a light emitting element ED (e.g., the light emitting element ED1) may be directed to the encapsulation layer ENCAP.

Further, another part of the light emitted from the light emitting element ED may be directed to the light path changing element 710. In this case, the light incident to the light path changing element 710 can be reflected from the light path changing element 710 and directed to the encapsulation layer ENCAP.

In an example where the light path changing element 710 is not included, a part of light emitted from the light emitting element ED may pass through the bank BK and be trapped inside of the display panel 110, and thus, the light efficiency of the display panel 110 may decrease.

In contrast, the display panel 110 according to the embodiments of the present disclosure can reduce the amount of light trapped inside of the display panel 110 due to the light path changing element 710 disposed on at least one side surface of the second planarization layer PLN2, and thereby, the amount of light directed to the outside of the display panel 110 can be increased.

Further, since the light path changing element 710 according to embodiments of the present disclosure is disposed on a portion of at least one side surface of the second planarization layer PLN2 formed by the concave portion 810, although the surface area of the light path changing element 710 is relatively large, the area of the light path changing element 710 occupied on a plane can be reduced, and thereby, an amount of reflected light among light emitted from the light emitting element ED can be increased. As a result, an area substantially occupied by the light path changing element 710 in the first optical area OA1 can be reduced, and the transmittance of the first optical area OA1 may not be greatly affected.

In one or more embodiments, the display device 100 according to aspects of the present disclosure may further include an auxiliary light emitting area surrounding each of the first and fourth light emitting areas (EA1 and EA4) disposed in the first optical area OA1.

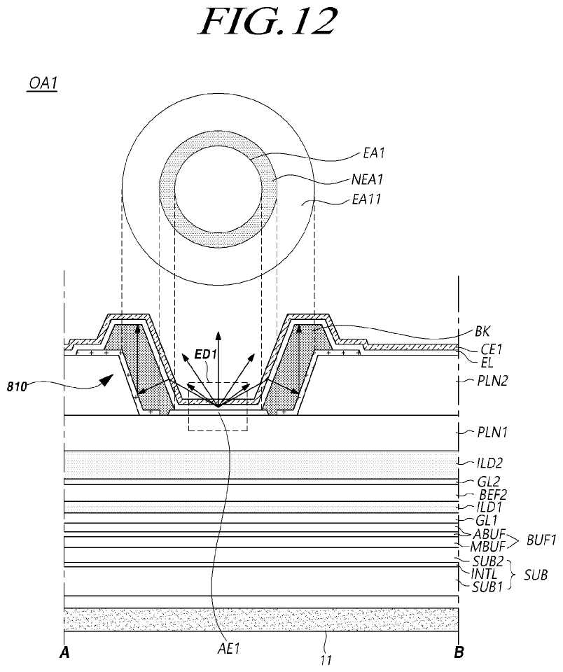

This configuration is described with reference to FIG. 12.

FIG. 12 illustrates an example first light emitting area and an example first auxiliary light emitting area included in the first optical area OA1 in the display panel 110 according to aspects of the present disclosure.

Referring to FIG. 12, the first optical area OA1 may include a first light emitting area EA1.

The first light emitting area EA1 may be defined by the bank BK. For example, the first light emitting area EA1 may be an area in which a first anode electrode AE1 not overlapping the bank BK is disposed.

Referring to FIG. 12, a first non-light emitting area NEA1 surrounding the first light emitting area EA1 may be disposed.

Referring to FIG. 12, a first auxiliary light emitting area EA11 surrounding the first non-light emitting area NEA1 may be disposed.

For example, the first non-light emitting area NEA1 may be an area between an area in which the first anode electrode AE1 not overlapping the bank BK is disposed and an area corresponding to at least one side surface of the second planarization layer PLN2 formed by the concave portion 810 (e.g., at least one inclined side of the planarization layer PLN2).

The first non-light emitting area NEA1 is in a black state when the display panel is in an on state, or may represent luminance lower than the first light emitting area EA1 and the first auxiliary light emitting area EA11 due to light incident from at least one of the first light emitting area EA1 and the first auxiliary light emitting area EA11.

The first auxiliary light emitting area EA1 may be an area corresponding to at least one inclined side surface formed by the concave portion 810 of the second planarization layer PLN2 in a cross-sectional view.

The first auxiliary light emitting area EA1 may be an area formed by reflection of light emitted from the first light emitting element ED1 from the light path changing element 710 disposed on at least one inclined side surface of the second planarization layer PLN2 formed by the concave portion 810 of the second planarization layer PLN2.

In one or more exemplary embodiments, a second non-light emitting area may be disposed such that it surrounds the first auxiliary light emitting area EA11.

Referring to FIG. 12, the second non-light emitting area may include a non-transmissive area and a transmissive area of the first optical area OA1. For example, the non-transmissive area included in the second non-light emitting area may be an area corresponding to an area where the light path changing element 710 is disposed on the upper surface of the second planarization layer PLN2. The transmissive area included in the second non-light emitting area may be area between the non-transmissive area included in the second non-light emitting area and a non-transmissive area included in a second non-light emitting area of another light emitting area adjacent to the first light emitting area EA1.

Thus, a light emitting area of the first optical area OA1 in the display panel 110 according to exemplary embodiments of the present disclosure can be increased by disposing the light path changing element 710.

Although FIG. 12 illustrates the first light emitting area EA1, the first non-light emitting area NEA1 surrounding the first light emitting area EA1, and the first auxiliary light emitting area EA11 surrounding the first non-light emitting area NEA1, configurations of the display panel 110 according to embodiments of the present disclosure are not limited thereto.

For example, in the same manner as the first light emitting area EA1, a first non-light emitting area surrounding the fourth light emitting area EA4 and a second auxiliary light emitting area surrounding the first non-light emitting area may be disposed around the fourth light emitting area EA4 disposed in the first optical area OA1.

In one or more exemplary embodiments, the second auxiliary light emitting area may be a light emitting area formed by reflection of light emitted from the fourth light emitting area ED4 from the light path changing element 710 disposed on at least one side surface of the second planarization layer PLN2 formed by the concave portion 810 of the second planarization layer PLN2.

Meanwhile, the example structures where the 1:1 circuit connection scheme as in FIG. 5 is applied has been described through FIGS. 8 to 11, but structures of the display panel 110 according to embodiments of the present disclosure are not limited thereto.

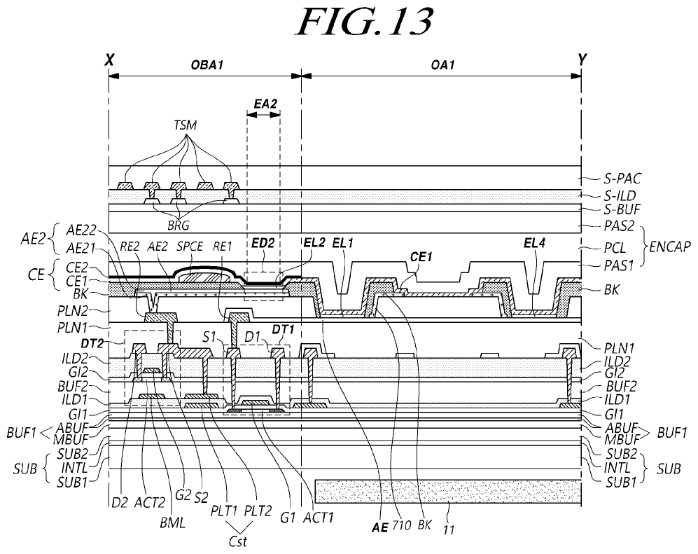

FIG. 13 is an example cross-sectional view of the display panel 110 according to aspects of the present disclosure in an example where the 1:2 circuit connection scheme as shown in FIG. 6 is applied.

Hereinafter, descriptions on the cross-sectional structure of FIG. 13 will be provided by focusing on features different from the cross-sectional structure of FIG. 8.

Referring to FIGS. 7 and 13, a first light emitting element ED1 and a fourth light emitting element ED4 disposed in the first optical area OA1 may be driven concurrently or together by a first driving transistor DT1 disposed in the first optical bezel area OBA1.

Accordingly, the first light emitting element EDI and the fourth light emitting element ED1 can share an anode electrode AE connected to the first driving transistor DT1.

Referring to FIGS. 7 and 13, a first light emitting area EA1 by the first light emitting element ED1 and a fourth light emitting area EA4 by the fourth light emitting element ED4 are light emitting areas emitting light of a same color, without being limited thereto.

In one or more exemplary embodiments, as shown in FIG. 12, an auxiliary light emitting area formed through a light path changing element 710 may be disposed around each or at least one of the first light emitting area EA1 and the fourth light emitting area EA4.

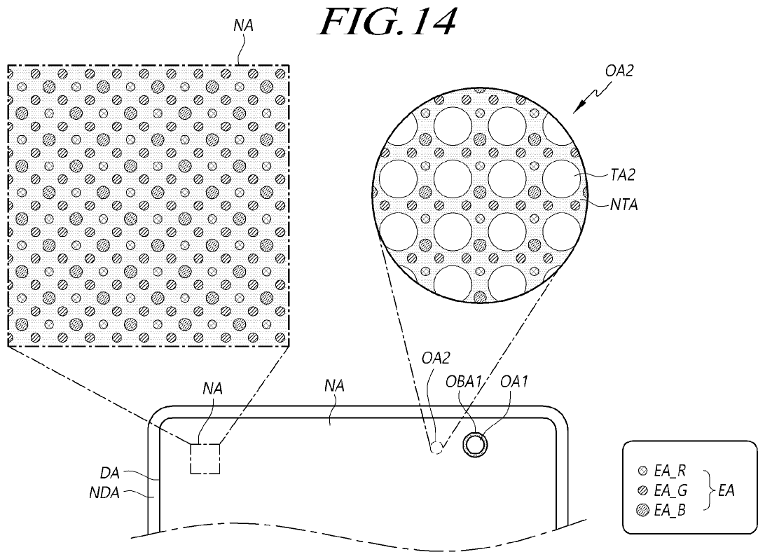

Hereinafter, a second optical area OA2 (e.g., the second optical area OA2 discussed above) according to embodiments of the present disclosure will be discussed with reference to FIG. 14.

FIG. 14 illustrates an example normal area NA, and an example second optical area OA2 included in the display panel 110 according to aspects of the present disclosure.

Referring to FIG. 14, the display area DA of the display panel 110 may further include the second optical area OA2 in addition to the normal area NA and the first optical area OA1.

The first optical area OA1 may be an area overlapping the first optical electronic device 11, and the second optical area OA2 may be an area overlapping the second optical electronic device 12.

The first optical electronic device 11 and the second optical electronic device 12 may be configured to use, or to be operated by, different wavelengths of light from each other, without being limited thereto. As an example, the first optical electronic device 11 and the second optical electronic device 12 may be configured to use, or to be operated by, the same wavelength of light.

For example, one of the first optical electronic device 11 and the second optical electronic device 12 may be a camera using visible light, and the other thereof may be a sensor using light of a wavelength band different from visible light (e.g. infrared light or ultraviolet light).

For example, the first optical electronic device 11 may be a camera, and the second optical electronic device 12 may be an infrared sensor.

Referring to FIG. 14, the second optical area OA2 may include a non-transmissive area NTA including a plurality of light emitting areas EA, and may further include at least one transmissive area TA.

As shown in FIG. 14, the second optical area OA2 may be designed in substantially the same manner as the configuration of the first optical area OA1. However, it should be noted that the first optical area OA1 and the second optical area OA2 may differ from each other in at least one of a pattern in which subpixels are arranged, locations in which subpixels are disposed, the number of subpixels per unit area, emission areas of subpixels, transmittance, and the like.

According to the embodiments described herein, the display panel 110 and the display device 100 may be provided that include a light transmission structure for enabling one or more optical electronic devices to normally receive light (e.g., visible light, infrared light, ultraviolet light, or the like) while not being exposed in a front surface of the display device.

According to the embodiments described herein, the display panel 110 and the display device 100 may be provided that are capable of more improving transmittance of an optical area by disposing light emitting elements in the optical area allowing light to be transmitted, but disposing pixel circuits for driving the light emitting elements of the optical area in an area outside of the optical area (e.g., an optical bezel area, a normal area).

According to the embodiments described herein, the display panel 110 and the display device 100 may be provided that include a structure of interconnecting, using anode extension lines, for example, including a transparent material, light emitting elements disposed in an optical area allowing light to be transmitted and pixel circuits (e.g., transistors included in the pixel circuits) disposed in an area outside of the optical area (e.g., an optical bezel area, a normal area), and thereby, are capable of increasingly improving transmittance of an optical area.

According to the embodiments described herein, the display panel 110 and the display device 100 may be provided that are capable of producing high luminance even when driven with low power by improving light extraction efficiency through a light path changing element disposed in an optical area.

According to the embodiments described herein, the display panel 110 and the display device 100 may be provided that allow a light path changing element and a cathode electrode disposed in an optical area to contact, and thereby, are capable of producing uniform luminance by reducing or preventing voltage drop in the cathode electrode.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device comprising:
a first optical area included in a display area in which an image is displayed, the first optical area configured to transmit light; and
a normal area included in the display area and located outside of the first optical area,
wherein the first optical area comprises:
a first anode electrode of a first light emitting element;
a first insulating layer comprising a concave portion exposing at least a portion of an upper surface of the first anode electrode; and
a light path changing element on at least one side surface of the concave portion.

2. The display device of claim 1, wherein the light path changing element is further on a portion of an upper surface of the first insulating layer; and
wherein the first optical area further comprises a bank exposing a portion of the light path changing element disposed that is on the upper surface of the first insulating layer and exposing a portion of the upper surface of the first anode electrode.

3. The display device of claim 2, wherein the first anode electrode is on a second insulating layer that is under the first insulating layer, and
wherein the light path changing element extends to a portion of an upper surface of the second insulating layer, and is spaced apart from the first anode electrode.

4. The display device of claim 2, wherein a first cathode electrode of the first light emitting element contacts a portion of the light path changing element exposed by the bank on the first insulating layer.

5. The display device of claim 1, further comprising:
a first optical bezel area located between the first optical area and the normal area,
wherein: a plurality of first light emitting elements comprising the first anode electrode, an emission layer, and a first cathode electrode are in the first optical area;
a plurality of second light emitting elements comprising a second anode electrode, an emission layer, the first cathode electrode, and a second cathode electrode are in the first optical bezel area; and
a plurality of third light emitting elements comprising a third anode electrode, an emission layer, the first cathode electrode, and the second cathode electrode are in the normal area.

6. The display device of claim 5, wherein the light path changing element is further disposed on a portion of an upper surface of the first insulating layer, and
wherein the first cathode electrode contacts the light path changing element not overlapping the emission layer of the first light emitting element on the first insulating layer.

7. The display device of claim 5, wherein the first optical area further comprises a bank exposing a portion of the upper surface of the first anode electrode, and
wherein the first optical area comprises a plurality of first light emitting areas, and a corresponding one of the plurality of first light emitting areas corresponds to an area in which the first anode electrode is non-overlapping with the bank.

8. The display device of claim 7, wherein the first optical area comprises a non-light emitting area surrounding the plurality of first light emitting areas, and an auxiliary light emitting area surrounding the non-light emitting area.

9. The display device of claim 8, wherein the auxiliary light emitting area is an area corresponding to at least one side surface of the concave portion formed in the first insulating layer, and the non-light emitting area is between the first plurality of light emitting areas and the auxiliary light emitting area.

10. The display device of claim 1, wherein the first optical area comprises a transmissive area and a non-transmissive area, and
wherein an area where the light path changing element is disposed is included in the non-transmissive area, and the remaining area of the first optical area except for the area where the light path changing element is disposed is included in the transmissive area.

11. The display device of claim 1, wherein the first optical area comprises a plurality of light emitting areas, and each of the light emitting areas is surrounded by an auxiliary light emitting area, and the auxiliary light emitting area overlaps an area where the light path changing element is disposed.

12. The display device of claim 1, wherein the light path changing element surrounds a portion of a light emitting area included in the first optical area.

13. The display device of claim 1, further comprising: a first optical electronic device overlapping the first optical area,
wherein the first optical electronic device receives light passing through the first optical area and performs a predefined operation by using the received light, and
wherein the light received by the first optical electronic device is visible light, infrared light, or ultraviolet light.

14. The display device of claim 1, further comprising: a second optical area included in the display area,
wherein the second optical area is identically configured with the first optical area.

15. The display device of claim 1, wherein at least one side edge of the first anode electrode is exposed by the concave portion, such that the at least one side edge is spaced apart from the first insulating layer.

16. The display device of claim 1, wherein the light path changing element includes a conductive material capable of reflecting light.

17. A display panel comprising:
a first optical area included in a display area in which an image is displayed and allowing light to be transmitted;
a normal area included in the display area and located outside of the first optical area; and
a first optical bezel area included in the display area and located between the first optical area and the normal area, the first optical area comprising:
a first anode electrode of a first light emitting element;
a first insulating layer comprising a concave portion exposing at least a portion of an upper surface of the first anode electrode;
a light path changing element on a portion of an upper surface of the first insulating layer and at least one side surface of the concave portion; and
a bank exposing a portion of the light path changing element on the upper surface of the first insulating layer and exposing a portion of the upper surface of the first anode electrode.

18. A display device comprising:
a substrate comprising a plurality of subpixels;
a transistor over the substrate;
a planarization layer on the transistor;
an anode electrode on the planarization layer;
at least one insulating layer covering a portion of the anode electrode and comprising at least one open area defining a light emitting area;
an organic layer and a cathode electrode on the at least one insulating layer; and,
a light path changing element surrounding the light emitting area and exposing at least one side of the light emitting area.

19. The display device of claim 18, wherein the anode electrode extends to the at least one side of the light emitting area exposed by the light path changing element and is connected to the transistor.

20. The display device of claim 18, wherein the anode electrode is spaced apart from the light path changing element.
